(19) United States
(12) Patent Application Publication
(10) Pub. No.: US 2022/0385796 A1
(43) Pub. Date: Dec. 1, 2022

(54) WEARABLE DEVICE APPLICATIONS

(71) Applicant: Meta Platforms Technologies, LLC, Menlo Park, CA (US)

(72) Inventors: Samuel Tam, Daly City, CA (US); Jianer Bao, Sunnyvale, CA (US); Alexander Hsing, Redondo Beach, CA (US); Alejandra Alvarez Albarran, Bellevue, WA (US); Jake Fine, New York, NY (US); Dong Rim Lee, San Jose, CA (US); Arman Boromand, Issaquah, WA (US); Alex Ockfen, Bothell, WA (US)

(21) Appl. No.: 17/879,688

(22) Filed: Aug. 2, 2022

Related U.S. Application Data
(60) Provisional application No. 63/257,433, filed on Oct. 19, 2021.
(60) Provisional application No. 63/298,294, filed on Jan. 11, 2022.
(60) Provisional application No. 63/347,385, filed on May 31, 2022.

(51) Int. Cl. H04N 5/225; H01L 27/146

(52) U.S. Cl. CPC H04N 5/2257; H01L 27/14636; H01L 27/14625; H01L 27/14634; H01L 27/1462

(57) ABSTRACT

A camera device for integration into a wearable device is presented. The camera device includes an image sensor, a lens assembly, a first high density interconnect (HDI) tape substrate, a second HDI tape substrate, and a molded plastic layer. The molded plastic layer is sandwiched between the first and second HDI tape substrates. A wearable device with at least one soft electrode is further presented. The at least one soft electrode includes a conductive coating applied to an elastomer substrate and monitors electrical signals generated by a wearer of the wearable device to initiate an appropriate action. A method of forming an aggregate coating for a wearable device is further presented. One or more thin films are applied to a surface of the wearable device, and a paint coating is applied to a surface of the one or more thin films to form the aggregate coating.

### CROSS REFERENCE TO RELATED APPLICATIONS

This application claims a priority and benefit to U.S. Provisional Patent Application Ser. No. 63/257,433, Oct. 19, 2021, U.S. Provisional Patent Application Ser. No. 63/298,294, filed Jan. 11, 2022, and U.S. Provisional Patent Application Ser. No. 63/347,385, filed May 31, 2022, each of which is hereby incorporated by reference in its entirety.

### FIELD OF THE INVENTION

The present disclosure relates generally to wearable devices, and specifically relates to wearable device applications.

### BACKGROUND

Cameras for wearable devices have increasingly small form factors. However, camera modules that are small in size, inexpensive to manufacture, durable, and reliable in operation, are very difficult to achieve.

Wearable devices sometimes include electrodes to measure electrical signals from a user. One of the challenges with available electrodes are making them comfortable for long term wear. Electrodes typically have to be in good contact with skin of the user and are made out of relatively stiff conductors and/or materials that can have bio-compatibility issues (e.g., nanowires embedded in elastomers), making them uncomfortable for long term wear.

Commercial off-the-shelf (OTS) paints and coatings for wearable devices are traditionally designed with a single objective, such as achieving a desired color, or to protect a surface from hostile environments. Moreover, such OTS products do not account for both minimizing heating of a wearable device (e.g., headset) from the sun and radiative cooling of heat produced by the wearable device.

### SUMMARY

Embodiments of the present disclosure relate to a camera device that can be integrated into a wearable device. The camera device includes an image sensor, a lens assembly configured to hold at least one lens, a first high density interconnect (HDI) tape substrate, a second HDI tape substrate, and a molded plastic layer. The first HDI tape substrate has a top surface and a bottom surface. The top surface of the first HDI tape substrate is coupled to the lens assembly. The first HDI tape substrate is coupled to the image sensor, and the first HDI tape substrate includes a first plurality of electrodes. The second HDI tape substrate includes a second plurality of electrodes and a plurality of components mounted on a top surface of the second HDI tape substrate. The molded plastic layer is sandwiched between the bottom surface of the first HDI tape substrate and the top surface of the second HDI tape substrate. The molded plastic layer includes one or more vias to interconnect at least one electrode of the first plurality of electrodes to at least one electrode of the second plurality of electrodes.

Embodiments of the present disclosure further relate to a wearable device (e.g., smartwatch) with one or more soft electrodes. The one or more soft electrodes comprise a conductive coating applied to an elastomer substrate. The one or more soft electrodes are configured to monitor one or more electrical signals generated by a wearer of the wearable device (i.e., user). A controller of the wearable device can be coupled to the one or more soft electrodes and configured to perform an action based in part on the one or more monitored electrical signals.

Embodiments of the present disclosure further relate to a method for coating of a wearable device (i.e., consumer electronic device, such as a headset). The method comprises: applying one or more thin films to a first surface of the wearable device; and applying a paint coating to a surface of the one or more thin films to form an aggregate coating for the wearable device. The aggregate coating has an emissivity distribution that includes an ultraviolet (UV) band, a near-infrared (NIR) band, a visible band, and a mid-to-far infrared (IR) band. The emissivity distribution in the UV and NIR bands is lower than the emissivity distribution in the visible band, and the emissivity distribution in the visible band is lower than the emissivity distribution in the mid-to-far IR band.

### BRIEF DESCRIPTION OF THE DRAWINGS

FIG. 1A is a perspective view of a headset implemented as an eyewear device, in accordance with one or more embodiments.

FIG. 1B is a perspective view of a headset implemented as a head-mounted display, in accordance with one or more embodiments.

FIG. 2 is a block diagram of an audio system, in accordance with one or more embodiments.

FIG. 3 illustrates an example process of packaging a camera device, in accordance with one or more embodiments.

FIG. 4A illustrates an example expanded view of the camera device packaged using the process in FIG. 3.

FIG. 4B illustrates another example expanded view of the camera device produced during the process in FIG. 3.

FIG. 5A is a cross section of an example structure of a camera device with an image sensor located on a top surface of a substrate, in accordance with one or more embodiments.

FIG. 5B is a cross section of an example structure of a camera device with an image sensor located within a cavity, in accordance with one or more embodiments.

FIG. 6 illustrates an example view of a band of a wearable device with one or more soft electrodes, in accordance with one or more embodiments.

FIG. 7 illustrates an example view of multiple soft electrodes coupled to a common bus for implementation within a wearable device, in accordance with one or more embodiments.

FIG. 8A illustrates an example spectral emissivity for black coating of a wearable device, in accordance with one or more embodiments.

FIG. 8B illustrates an example spectral emissivity for green coating of a wearable device, in accordance with one or more embodiments.

FIG. 9 illustrates an example aggregate coating for a wearable device, in accordance with one or more embodiments.

FIG. 10 is a flowchart illustrating a process for coating of a wearable device, in accordance with one or more embodiments.

FIG. 11 depicts a block diagram of a system that includes a wearable device (e.g., headset), in accordance with one or more embodiments.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

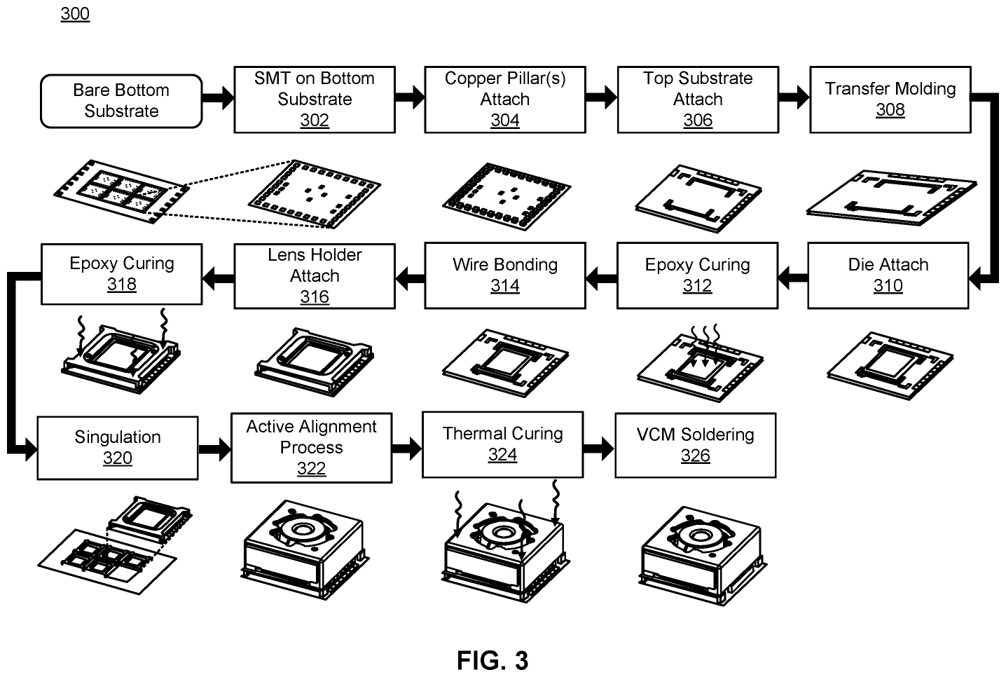

Embodiments of the present disclosure relate to various wearable device applications. A camera device for integration into a wearable device can be packaged using a process presented in this disclosure. The process may populate different surface mount technology (SMT) components (e.g., passive devices, dummies, and interconnects) on a side of a first high density interface (HDI) tape substrate. The process may utilize one or more pillars within the first HDI tape substrate to make interconnections to a second HDI tape substrate. A transfer molding may fill an encapsulant in between the first HDI tape substrate and the second HDI tape substrate. An image sensor may be positioned on the second HDI tape substrate (e.g., in a cavity of the second HDI tape substrate). Details about the process of packaging a camera device within a wearable device are provided below in relation to FIGS. 3 through 5B.

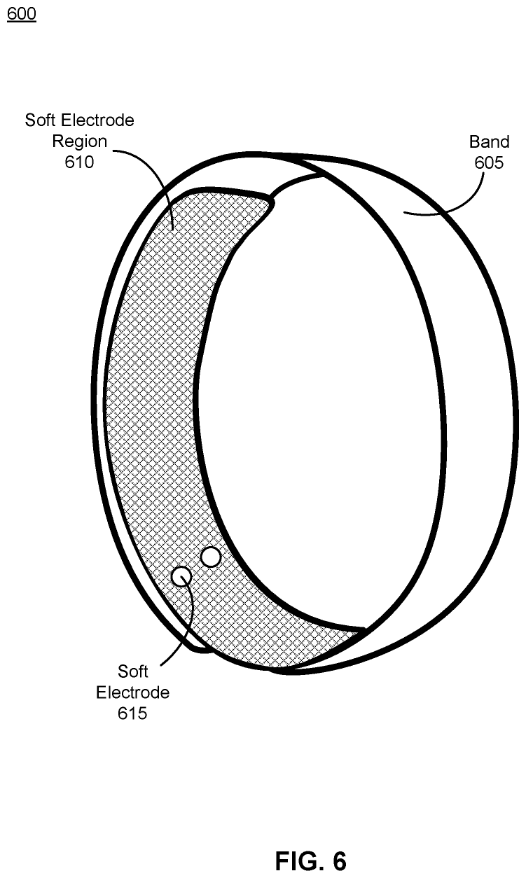

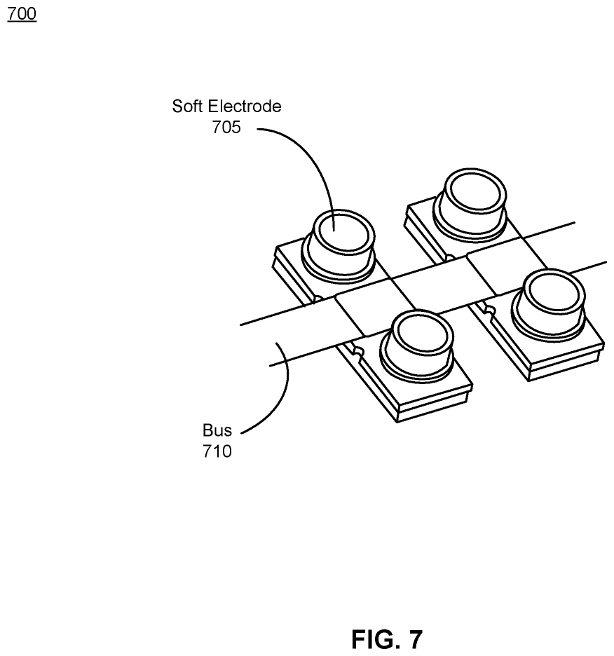

Some embodiments of the present disclosure are directed to soft electrodes for wearable devices. The soft electrodes may be based on a flexible elastomer (e.g., rubber) that is coated with a conductive version of a diamond like carbon (DLC) material. One or more features of the DLC material can be tuned through, e.g., sp2 layer hybridization and/or sp3 layer hybridization. A preferred bonding between the DLC material and the elastomer may be achieved by, e.g., plasma treatment of a substrate of the elastomer before the DLC deposition. Details about a structure and implementation of soft electrodes for wearable devices are provided below in relation to FIG. 6 and FIG. 7.

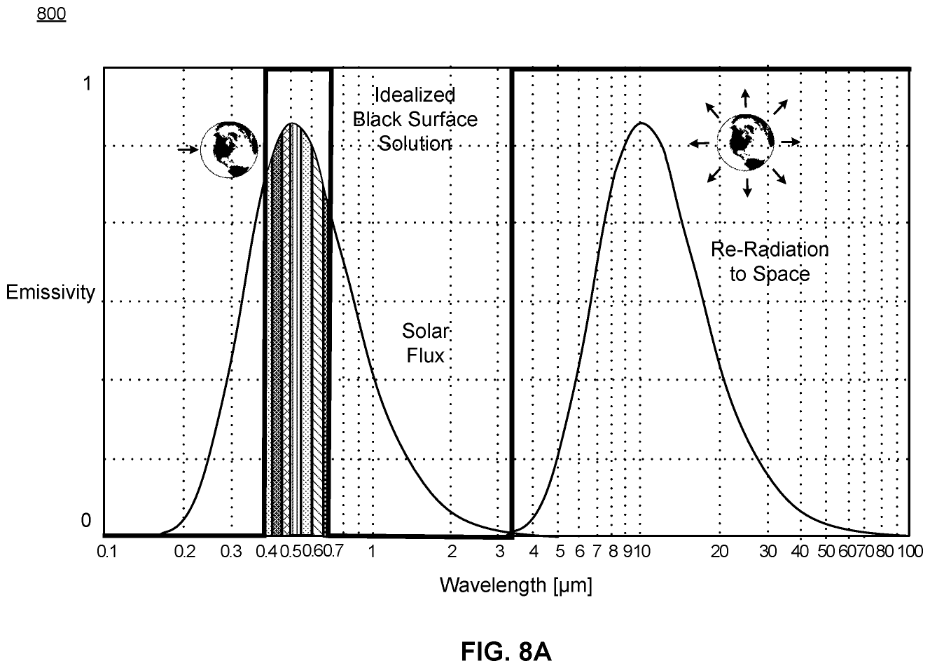

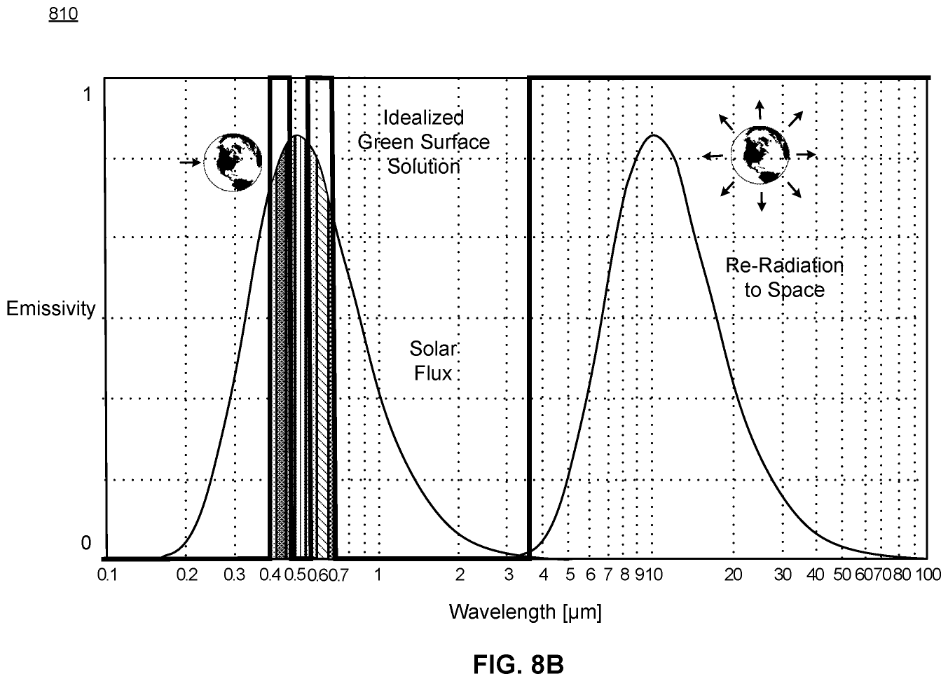

Some embodiments of the present disclosure are directed to a process of coating of a wearable device (e.g., a headset). The coating applied to the wearable device may present as a particular color and has increased reflective cooling for solar flux (e.g., ultraviolet (UV) into near-infrared (NIR)), while having high emissivity in the mid-to-far infrared (IR) (e.g., heat emitted by the wearable device). A substrate (e.g., frame of the wearable device) may be coated via physical vapor deposition (PVD) and/or polyvinyl chloride (PVC) deposition with a reflective coating (e.g., of approximately 2 μm thickness) that is reflective to solar flux and has high emissivity for lower wavelengths. A second ‘color’ coating or paint (e.g., of approximately 20 μm thickness) may be applied over the reflective coating to form an aggregate coating. The second coating may be configured (e.g., via embedding particles) to absorb and/or scatter light in certain bands while being transparent to light outside these bands. In other embodiments, the substrate is composed of ultra-high molecular weight polyethylene (UHMWPE) (e.g., for solar reflectivity), and is then coated with an UV/IR transparent tint coating (e.g., for aesthetics) to form the aggregate coating. More details about the process of forming an aggregate coating for a wearable device are provided below in relation to FIGS. 8A through 10.

Embodiments of the present disclosure may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to create content in an artificial reality and/or are otherwise used in an artificial reality. The artificial reality system that provides the artificial reality content may be implemented on various platforms, including a wearable device (e.g., headset, smartwatch, etc.) connected to a host computer system, a standalone wearable device (e.g., headset, smartwatch, etc.), a mobile device or computing system, or any other hardware platform capable of providing artificial reality content to one or more viewers.

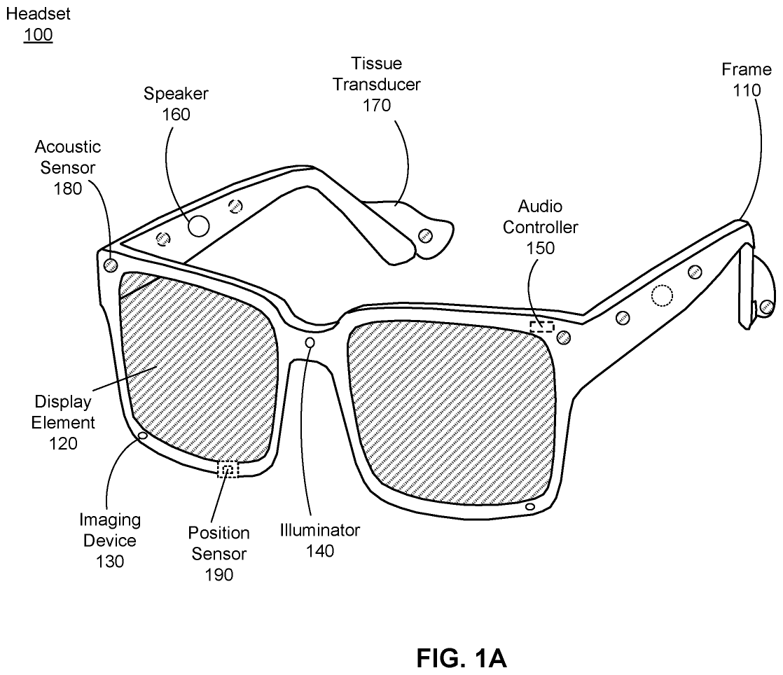

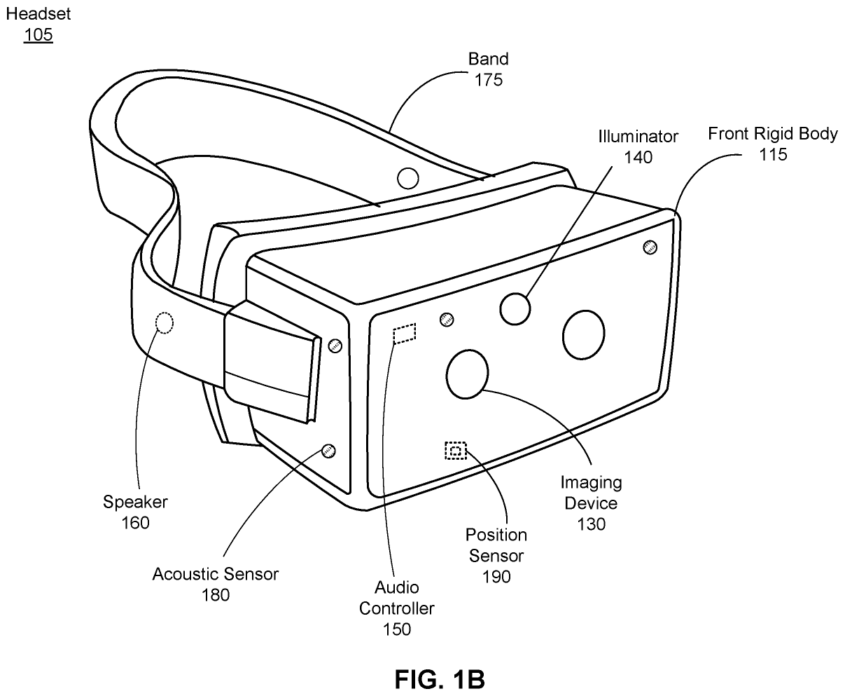

FIG. 1A is a perspective view of a headset 100 implemented as an eyewear device, in accordance with one or more embodiments. In some embodiments, the eyewear device is a near eye display (NED). In general, the headset 100 may be worn on the face of a user such that content (e.g., media content) is presented using a display assembly and/or an audio system. However, the headset 100 may also be used such that media content is presented to a user in a different manner. Examples of media content presented by the headset 100 include one or more images, video, audio, or some combination thereof. The headset 100 includes a frame 110, and may include, among other components, a display assembly including one or more display elements 120, a depth camera assembly (DCA), an audio system, and a position sensor 190. While FIG. 1A illustrates the components of the headset 100 in example locations on the headset 100, the components may be located elsewhere on the headset 100, on a peripheral device paired with the headset 100, or some combination thereof. Similarly, there may be more or fewer components on the headset 100 than what is shown in FIG. 1A.

The frame 110 holds the other components of the headset 100. The frame 110 includes a front part that holds the one or more display elements 120 and end pieces (e.g., temples) to attach to a head of the user. The front part of the frame 110 bridges the top of a nose of the user. The length of the end pieces may be adjustable (e.g., adjustable temple length) to fit different users. The end pieces of the frame 110 may also include a portion that curls behind the ear of the user (e.g., temple tip, earpiece).

Some embodiments of the present disclosure relate to an aggregate coating of the frame 110 that is designed as a solar heat reflective and device radiative aesthetic coating. Details about the (aggregated) coating of the frame 110 are provided below in relation to FIGS. 8A through 10.

The one or more display elements 120 provide light to a user wearing the headset 100. As illustrated in FIG. 1A, the headset includes a display element 120 for each eye of a user. In some embodiments, a display element 120 generates image light that is provided to an eye box of the headset 100. The eye box is a location in space that an eye of the user occupies while wearing the headset 100. For example, a display element 120 may be a waveguide display. A waveguide display includes a light source (e.g., a two-dimensional source, one or more line sources, one or more point sources, etc.) and one or more waveguides. Light from the light source is in-coupled into the one or more waveguides which outputs the light in a manner such that there is pupil replication in an eye box of the headset 100. In-coupling and/or outcoupling of light from the one or more waveguides may be done using one or more diffraction gratings. In some embodiments, the waveguide display includes a scanning element (e.g., waveguide, mirror, etc.) that scans light from the light source as it is in-coupled into the one or more waveguides. Note that in some embodiments, one or both of the display elements 120 are opaque and do not transmit light from a local area around the headset 100. The local area is the area surrounding the headset 100. For example, the local area may be a room that a user wearing the headset 100 is inside, or the user wearing the headset 100 may be outside and the local area is an outside area. In this context, the headset 100 generates VR content. Alternatively, in some embodiments, one or both of the display elements 120 are at least partially transparent, such that light from the local area may be combined with light from the one or more display elements to produce AR and/or MR content.

In some embodiments, a display element 120 does not generate image light, and instead is a lens that transmits light from the local area to the eye box. For example, one or both of the display elements 120 may be a lens without correction (non-prescription) or a prescription lens (e.g., single vision, bifocal and trifocal, or progressive) to help correct for defects in a user's eyesight. In some embodiments, the display element 120 may be polarized and/or tinted to protect the user's eyes from the sun.

In some embodiments, the display element 120 may include an additional optics block (not shown). The optics block may include one or more optical elements (e.g., lens, Fresnel lens, etc.) that direct light from the display element 120 to the eye box. The optics block may, e.g., correct for aberrations in some or all of the image content, magnify some or all of the image, or some combination thereof.

The DCA determines depth information for a portion of a local area surrounding the headset 100. The DCA includes one or more imaging devices 130 and a DCA controller (not shown in FIG. 1A), and may also include an illuminator 140. In some embodiments, the illuminator 140 illuminates a portion of the local area with light. The light may be, e.g., structured light (e.g., dot pattern, bars, etc.) in the IR, IR flash for time-of-flight, etc. In some embodiments, the one or more imaging devices 130 capture images of the portion of the local area that include the light from the illuminator 140. As illustrated, FIG. 1A shows a single illuminator 140 and two imaging devices 130. In alternate embodiments, there is no illuminator 140 and at least two imaging devices 130.

Some embodiments of the present disclosure relate to a process of packaging the imaging device 130 into the headset 100. Details about the packaging process for the imaging device 130 are provided below in relation to FIGS. 3 through 5B.

The DCA controller computes depth information for the portion of the local area using the captured images and one or more depth determination techniques. The depth determination technique may be, e.g., direct time-of-flight (ToF) depth sensing, indirect ToF depth sensing, structured light, passive stereo analysis, active stereo analysis (uses texture added to the scene by light from the illuminator 140), some other technique to determine depth of a scene, or some combination thereof.

The audio system provides audio content. The audio system includes a transducer array, a sensor array, and an audio controller 150. However, in other embodiments, the audio system may include different and/or additional components. Similarly, in some cases, functionality described with reference to the components of the audio system can be distributed among the components in a different manner than is described here. For example, some or all of the functions of the audio controller 150 may be performed by a remote server.

The transducer array presents sound to user. The transducer array includes a plurality of transducers. A transducer may be a speaker 160 or a tissue transducer 170 (e.g., a bone conduction transducer or a cartilage conduction transducer). Although the speakers 160 are shown exterior to the frame 110, the speakers 160 may be enclosed in the frame 110. The tissue transducer 170 couples to the head of the user and directly vibrates tissue (e.g., bone or cartilage) of the user to generate sound. In accordance with embodiments of the present disclosure, the transducer array comprises two transducers (e.g., two speakers 160, two tissue transducers 170, or one speaker 160 and one tissue transducer 170), i.e., one transducer for each ear. The locations of transducers may be different from what is shown in FIG. 1A.

The sensor array detects sounds within the local area of the headset 100. The sensor array includes a plurality of acoustic sensors 180. An acoustic sensor 180 captures sounds emitted from one or more sound sources in the local area (e.g., a room). Each acoustic sensor is configured to detect sound and convert the detected sound into an electronic format (analog or digital). The acoustic sensors 180 may be acoustic wave sensors, microphones, sound transducers, or similar sensors that are suitable for detecting sounds.

In some embodiments, one or more acoustic sensors 180 may be placed in an ear canal of each ear (e.g., acting as binaural microphones). In some embodiments, the acoustic sensors 180 may be placed on an exterior surface of the headset 100, placed on an interior surface of the headset 100, separate from the headset 100 (e.g., part of some other device), or some combination thereof. The number and/or locations of acoustic sensors 180 may be different from what is shown in FIG. 1A. For example, the number of acoustic detection locations may be increased to increase the amount of audio information collected and the sensitivity and/or accuracy of the information. The acoustic detection locations may be oriented such that the microphone is able to detect sounds in a wide range of directions surrounding the user wearing the headset 100.

The audio controller 150 processes information from the sensor array that describes sounds detected by the sensor array. The audio controller 150 may comprise a processor and a non-transitory computer-readable storage medium. The audio controller 150 may be configured to generate direction of arrival (DOA) estimates, generate acoustic transfer functions (e.g., array transfer functions and/or head-related transfer functions), track the location of sound sources, form beams in the direction of sound sources, classify sound sources, generate sound filters for the speakers 160, or some combination thereof.

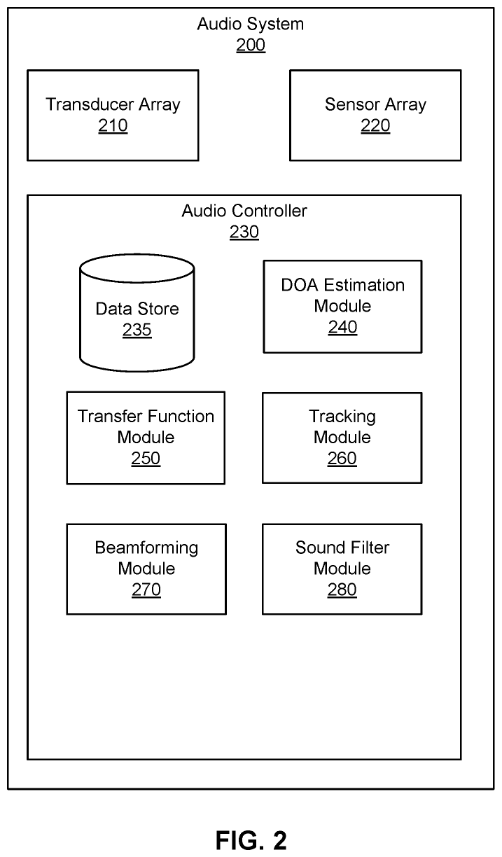

In some embodiments, the audio system is fully integrated into the headset 100. In some other embodiments, the audio system is distributed among multiple devices, such as between a computing device (e.g., smart phone or a console) and the headset 100. The computing device may be interfaced (e.g., via a wired or wireless connection) with the headset 100. In such cases, some of the processing steps presented herein may be performed at a portion of the audio system integrated into the computing device. For example, one or more functions of the audio controller 150 may be implemented at the computing device. More details about the structure and operations of the audio system are described in connection with FIG. 2.

The position sensor 190 generates one or more measurement signals in response to motion of the headset 100. The position sensor 190 may be located on a portion of the frame 110 of the headset 100. The position sensor 190 may include an IMU. Examples of position sensor 190 include: one or more accelerometers, one or more gyroscopes, one or more magnetometers, another suitable type of sensor that detects motion, a type of sensor used for error correction of the IMU, or some combination thereof. The position sensor 190 may be located external to the IMU, internal to the IMU, or some combination thereof.

The audio system can use positional information describing the headset 100 (e.g., from the position sensor 190) to update virtual positions of sound sources so that the sound sources are positionally locked relative to the headset 100. In this case, when the user wearing the headset 100 turns their head, virtual positions of the virtual sources move with the head. Alternatively, virtual positions of the virtual sources are not locked relative to an orientation of the headset 100. In this case, when the user wearing the headset 100 turns their head, apparent virtual positions of the sound sources would not change.

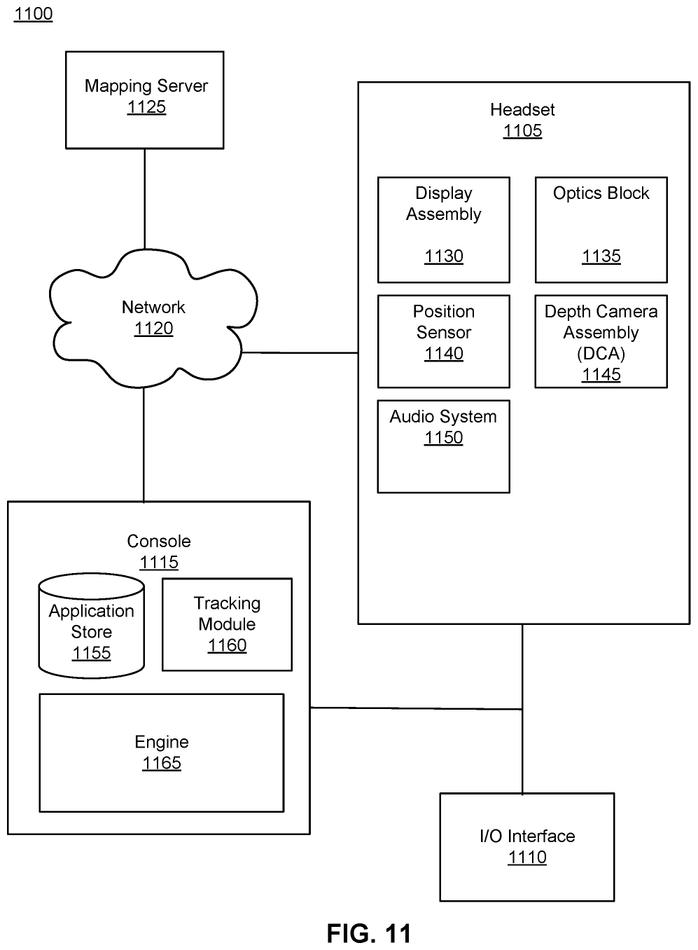

In some embodiments, the headset 100 may provide for simultaneous localization and mapping (SLAM) for a position of the headset 100 and updating of a model of the local area. For example, the headset 100 may include a passive camera assembly (PCA) that generates color image data. The PCA may include one or more RGB cameras that capture images of some or all of the local area. In some embodiments, some or all of the imaging devices 130 of the DCA may also function as the PCA. The images captured by the PCA and the depth information determined by the DCA may be used to determine parameters of the local area, generate a model of the local area, update a model of the local area, or some combination thereof. Furthermore, the position sensor 190 tracks the position (e.g., location and pose) of the headset 100 within the room. Additional details regarding the components of the headset 100 are discussed below in connection with FIG. 2 and FIG. 11.

FIG. 1B is a perspective view of a headset 105 implemented as a head-mounted display (HMD), in accordance with one or more embodiments. In embodiments that describe an AR system and/or a MR system, portions of a front side of the HMD are at least partially transparent in the visible band (˜380 nm to 750 nm), and portions of the HMD that are between the front side of the HMD and an eye of the user are at least partially transparent (e.g., a partially transparent electronic display). The HMD includes a front rigid body 115 and a band 175. The headset 105 includes many of the same components described above with reference to FIG. 1A, but modified to integrate with the HMD form factor. For example, the HMD includes a display assembly, a DCA, an audio system, and a position sensor 190. FIG. 1B shows the illuminator 140, a plurality of the speakers 160, a plurality of the imaging devices 130, a plurality of acoustic sensors 180, and the position sensor 190. The speakers 160 may be located in various locations, such as coupled to the band 175 (as shown), coupled to the front rigid body 115, or may be configured to be inserted within the ear canal of a user.

FIG. 2 is a block diagram of an audio system 200, in accordance with one or more embodiments. The audio system in FIG. 1A or FIG. 1B may be an embodiment of the audio system 200, i.e., the audio system 200 may be integrated into a wearable device (e.g., headset). The audio system 200 generates one or more acoustic transfer functions for a user. The audio system 200 may then use the one or more acoustic transfer functions to generate audio content for the user. In the embodiment of FIG. 2, the audio system 200 includes a transducer array 210, a sensor array 220, and an audio controller 230. Some embodiments of the audio system 200 have different components than those described here. Similarly, in some cases, functions can be distributed among the components in a different manner than is described here.

The transducer array 210 is configured to present audio content. The transducer array 210 includes a pair of transducers, i.e., one transducer for each ear. A transducer is a device that provides audio content. A transducer may be, e.g., a speaker (e.g., the speaker 160), a tissue transducer (e.g., the tissue transducer 170), some other device that provides audio content, or some combination thereof. A tissue transducer may be configured to function as a bone conduction transducer or a cartilage conduction transducer. The transducer array 210 may present audio content via air conduction (e.g., via one or two speakers), via bone conduction (via one or two bone conduction transducer), via cartilage conduction audio system (via one or two cartilage conduction transducers), or some combination thereof.

The bone conduction transducers generate acoustic pressure waves by vibrating bone/tissue in the user's head. A bone conduction transducer may be coupled to a portion of a headset, and may be configured to be behind the auricle coupled to a portion of the user's skull. The bone conduction transducer receives vibration instructions from the audio controller 230, and vibrates a portion of the user's skull based on the received instructions. The vibrations from the bone conduction transducer generate a tissue-borne acoustic pressure wave that propagates toward the user's cochlea, bypassing the eardrum.

The cartilage conduction transducers generate acoustic pressure waves by vibrating one or more portions of the auricular cartilage of the ears of the user. A cartilage conduction transducer may be coupled to a portion of a headset, and may be configured to be coupled to one or more portions of the auricular cartilage of the ear. For example, the cartilage conduction transducer may couple to the back of an auricle of the ear of the user. The cartilage conduction transducer may be located anywhere along the auricular cartilage around the outer ear (e.g., the pinna, the tragus, some other portion of the auricular cartilage, or some combination thereof). Vibrating the one or more portions of auricular cartilage may generate: airborne acoustic pressure waves outside the ear canal; tissue born acoustic pressure waves that cause some portions of the ear canal to vibrate thereby generating an airborne acoustic pressure wave within the ear canal; or some combination thereof. The generated airborne acoustic pressure waves propagate down the ear canal toward the ear drum.

The transducer array 210 generates audio content in accordance with instructions from the audio controller 230. In some embodiments, the audio content is spatialized. Spatialized audio content is audio content that appears to originate from a particular direction and/or target region (e.g., an object in the local area and/or a virtual object). For example, spatialized audio content can make it appear that sound is originating from a virtual singer across a room from a user of the audio system 200. The transducer array 210 may be coupled to a wearable device (e.g., the headset 100 or the headset 105). In alternate embodiments, the transducer array 210 may be a pair of speakers that are separate from the wearable device (e.g., coupled to an external console).

The sensor array 220 detects sounds within a local area surrounding the sensor array 220. The sensor array 220 may include a plurality of acoustic sensors that each detect air pressure variations of a sound wave and convert the detected sounds into an electronic format (analog or digital). The plurality of acoustic sensors may be positioned on a headset (e.g., headset 100 and/or the headset 105), on a user (e.g., in an ear canal of the user), on a neckband, or some combination thereof. An acoustic sensor may be, e.g., a microphone, a vibration sensor, an accelerometer, or any combination thereof. In some embodiments, the sensor array 220 is configured to monitor the audio content generated by the transducer array 210 using at least some of the plurality of acoustic sensors. Increasing the number of sensors may improve the accuracy of information (e.g., directionality) describing a sound field produced by the transducer array 210 and/or sound from the local area.

The audio controller 230 controls operation of the audio system 200. In the embodiment of FIG. 2, the audio controller 230 includes a data store 235, a DOA estimation module 240, a transfer function module 250, a tracking module 260, a beamforming module 270, and a sound filter module 280. The audio controller 230 may be located inside a headset, in some embodiments. Some embodiments of the audio controller 230 have different components than those described here. Similarly, functions can be distributed among the components in different manners than described here. For example, some functions of the audio controller 230 may be performed external to the headset. The user may opt in to allow the audio controller 230 to transmit data captured by the headset to systems external to the headset, and the user may select privacy settings controlling access to any such data.

The data store 235 stores data for use by the audio system 200. Data in the data store 235 may include sounds recorded in the local area of the audio system 200, audio content, HRTFs, transfer functions for one or more sensors, array transfer functions (ATFs) for one or more of the acoustic sensors, sound source locations, virtual model of local area, direction of arrival estimates, sound filters, virtual positions of sound sources, multi-source audio signals, signals for transducers (e.g., speakers) for each ear, and other data relevant for use by the audio system 200, or any combination thereof. The data store 235 may be implemented as a non-transitory computer-readable storage medium.

The user may opt-in to allow the data store 235 to record data captured by the audio system 200. In some embodiments, the audio system 200 may employ always on recording, in which the audio system 200 records all sounds captured by the audio system 200 in order to improve the experience for the user. The user may opt in or opt out to allow or prevent the audio system 200 from recording, storing, or transmitting the recorded data to other entities.

The DOA estimation module 240 is configured to localize sound sources in the local area based in part on information from the sensor array 220. Localization is a process of determining where sound sources are located relative to the user of the audio system 200. The DOA estimation module 240 performs a DOA analysis to localize one or more sound sources within the local area. The DOA analysis may include analyzing the intensity, spectra, and/or arrival time of each sound at the sensor array 220 to determine the direction from which the sounds originated. In some cases, the DOA analysis may include any suitable algorithm for analyzing a surrounding acoustic environment in which the audio system 200 is located.

For example, the DOA analysis may be designed to receive input signals from the sensor array 220 and apply digital signal processing algorithms to the input signals to estimate a direction of arrival. These algorithms may include, for example, delay and sum algorithms where the input signal is sampled, and the resulting weighted and delayed versions of the sampled signal are averaged together to determine a DOA. A least mean squared (LMS) algorithm may also be implemented to create an adaptive filter. This adaptive filter may then be used to identify differences in signal intensity, for example, or differences in time of arrival. These differences may then be used to estimate the DOA. In another embodiment, the DOA may be determined by converting the input signals into the frequency domain and selecting specific bins within the time-frequency (TF) domain to process. Each selected TF bin may be processed to determine whether that bin includes a portion of the audio spectrum with a direct path audio signal. Those bins having a portion of the direct-path signal may then be analyzed to identify the angle at which the sensor array 220 received the direct-path audio signal. The determined angle may then be used to identify the DOA for the received input signal. Other algorithms not listed above may also be used alone or in combination with the above algorithms to determine DOA.

In some embodiments, the DOA estimation module 240 may also determine the DOA with respect to an absolute position of the audio system 200 within the local area. The position of the sensor array 220 may be received from an external system (e.g., some other component of a headset, an artificial reality console, a mapping server, a position sensor (e.g., the position sensor 190, etc.). The external system may create a virtual model of the local area, in which the local area and the position of the audio system 200 are mapped. The received position information may include a location and/or an orientation of some or all of the audio system 200 (e.g., of the sensor array 220). The DOA estimation module 240 may update the estimated DOA based on the received position information.

The transfer function module 250 is configured to generate one or more acoustic transfer functions. Generally, a transfer function is a mathematical function giving a corresponding output value for each possible input value. Based on parameters of the detected sounds, the transfer function module 250 generates one or more acoustic transfer functions associated with the audio system. The acoustic transfer functions may be anatomical transfer functions (ATFs), head-related transfer functions (HRTFs), other types of acoustic transfer functions, or some combination thereof.

An ATF characterizes how the microphone receives a sound from a point in space. An ATF includes a number of transfer functions that characterize a relationship between the sound source and the corresponding sound received by the acoustic sensors in the sensor array 220. Accordingly, for a sound source there is a corresponding transfer function for each of the acoustic sensors in the sensor array 220. And collectively the set of transfer functions is referred to as an ATF. Accordingly, for each sound source there is a corresponding ATF. Note that the sound source may be, e.g., someone or something generating sound in the local area, the user, or one or more transducers of the transducer array 210. The ATF for a particular sound source location relative to the sensor array 220 may differ from user to user due to a person's anatomy (e.g., ear shape, shoulders, etc.) that affects the sound as it travels to the person's ears. Accordingly, the ATFs of the sensor array 220 are personalized for each user of the audio system 200.

In some embodiments, the transfer function module 250 determines one or more HRTFs for a user of the audio system 200. The HRTF characterizes how an ear receives a sound from a point in space. The HRTF for a particular source location relative to a person is unique to each ear of the person (and is unique to the person) due to the person's anatomy (e.g., ear shape, shoulders, etc.) that affects the sound as it travels to the person's ears. In some embodiments, the transfer function module 250 may determine HRTFs for the user using a calibration process. In some embodiments, the transfer function module 250 may provide information about the user to a remote system. The user may adjust privacy settings to allow or prevent the transfer function module 250 from providing the information about the user to any remote systems. The remote system determines a set of HRTFs that are customized to the user using, e.g., machine learning, and provides the customized set of HRTFs to the audio system 200.

The tracking module 260 is configured to track locations of one or more sound sources. The tracking module 260 may compare current DOA estimates and compare them with a stored history of previous DOA estimates. In some embodiments, the audio system 200 may recalculate DOA estimates on a periodic schedule, such as once per second, or once per millisecond. The tracking module may compare the current DOA estimates with previous DOA estimates, and in response to a change in a DOA estimate for a sound source, the tracking module 260 may determine that the sound source moved. In some embodiments, the tracking module 260 may detect a change in location based on visual information received from the headset or some other external source. The tracking module 260 may track the movement of one or more sound sources over time. The tracking module 260 may store values for a number of sound sources and a location of each sound source at each point in time. In response to a change in a value of the number or locations of the sound sources, the tracking module 260 may determine that a sound source moved. The tracking module 260 may calculate an estimate of the localization variance. The localization variance may be used as a confidence level for each determination of a change in movement.

The beamforming module 270 is configured to process one or more ATFs to selectively emphasize sounds from sound sources within a certain area while de-emphasizing sounds from other areas. In analyzing sounds detected by the sensor array 220, the beamforming module 270 may combine information from different acoustic sensors to emphasize sound associated from a particular region of the local area while deemphasizing sound that is from outside of the region. The beamforming module 270 may isolate an audio signal associated with sound from a particular sound source from other sound sources in the local area based on, e.g., different DOA estimates from the DOA estimation module 240 and the tracking module 260. The beamforming module 270 may thus selectively analyze discrete sound sources in the local area. In some embodiments, the beamforming module 270 may enhance a signal from a sound source. For example, the beamforming module 270 may apply sound filters which eliminate signals above, below, or between certain frequencies. Signal enhancement acts to enhance sounds associated with a given identified sound source relative to other sounds detected by the sensor array 220.

The sound filter module 280 determines sound filters for the transducer array 210. In some embodiments, the sound filters cause the audio content to be spatialized, such that the audio content appears to originate from a target region. The sound filter module 280 may use HRTFs and/or acoustic parameters to generate the sound filters. The acoustic parameters describe acoustic properties of the local area. The acoustic parameters may include, e.g., a reverberation time, a reverberation level, a room impulse response, etc. In some embodiments, the sound filter module 280 calculates one or more of the acoustic parameters. In some embodiments, the sound filter module 280 requests the acoustic parameters from a mapping server (e.g., as described below in relation to FIG. 11).

The sound filter module 280 provides the sound filters to the transducer array 210. In some embodiments, the sound filters may cause positive or negative amplification of sounds as a function of frequency. In some embodiments, audio content presented by the transducer array 210 is multi-channel spatialized audio. Spatialized audio content is audio content that appears to originate from a particular direction and/or target region (e.g., an object in the local area and/or a virtual object). For example, spatialized audio content can make it appear that sound is originating from a virtual singer across a room from a user of the audio system 200.

### Camera Device Packaging Process Sandwich Molding Technique

Some embodiments of the present disclosure are directed to a process of packaging a camera device for integration into a wearable device (e.g., smartwatch, headset, etc.). The packaging process presented herein utilized a sandwich molding technique. FIG. 3 illustrates an example process 300 of packaging a camera device, in accordance with one or more embodiments. The process 300 may include additional or fewer steps than what is shown in FIG. 3. The process 300 may utilize at least two HDI tape substrates. Each of the HDI tape substrates used in the process 300 may be very thin HDI tape substrates, which facilitates a small form factor of the camera device.

At 302, multiple SMT components may be placed on a first HDI tape substrate (e.g., bare bottom substrate). The SMT components (e.g., gyros, electrically erasable programmable read-only memory (EEPROM), controller, resistors, capacitors, etc.) may be populated inside a surface of the first HDI tape substrate. At 304, one or more copper pillars may be attached to the first HDI tape substrate. The one or more copper pillars may be utilized to reflow within a perimeter area of the first HDI tape substrate to make interconnection to a second HDI tape substrate (e.g., top substrate). At 306, the second HDI tape substrate may be attached to the one or more copper pillars. At 308, a transfer molding may be applied in between the first and second HDI tape substrates. A sandwich transfer molding technique may be used to fill an encapsulant in between the first HDI tape substrate and the second HDI tape substrate.

At 310, a die may be attached (i.e., bonded) to the second HDI tape substrate (e.g., top substrate). At 312, the epoxy curing of the attached die may be performed to improve bonding. At 314, the wire bonding may be applied onto the cured die. At 316, a lens holder may be attached onto the die. At 318, the epoxy curing for the attached lens holder may be performed to improve bonding of the lens. At 320, the singulation (i.e., dicing) is performed to divide a wafer into individual chips. At 322, the active alignment process may be performed. At 324, the thermal curing may be performed Finally, at 326, the soldering of a voice coil motor (VCM) may be applied. The process 300 for packaging of the camera device may provide a platform to embed various discrete SMT components inside the HDI tape substrates with flatness and rigidity. Moreover, the process 300 may allow SMT components to be stacked on top for vertical integration (i.e., three-dimensional integration).

There are several benefits of the camera packaging process 300 presented herein. Various discrete components such as EEPROM, controller, gyros, etc. may be placed inside the camera device. By integrating the discrete components inside the camera device, the cost of additional flexible substrate is avoided, and the overall manufacturing cost is reduced. The overall size of the camera device is reduced while achieving a clean module look with less substrate bending in the camera system. With close proximity of the image sensor, shorter signal routing can be achieved. By utilizing the transfer molding, better rigidity and support for the camera device can be achieved, as well as a smaller substrate surface area which is beneficial for efficient signal routing (e.g., by using anisotropic conductive film). The process 300 represents a unique way to package all components inside a camera device for a new complete look and easier handling and transferring on the system level assembly. The process 300 may provide a much better yield and be cheaper in total bills of material (BOM) and assembly cost in comparison to the traditional embedded printed circuit board (PCB) substrate technology.

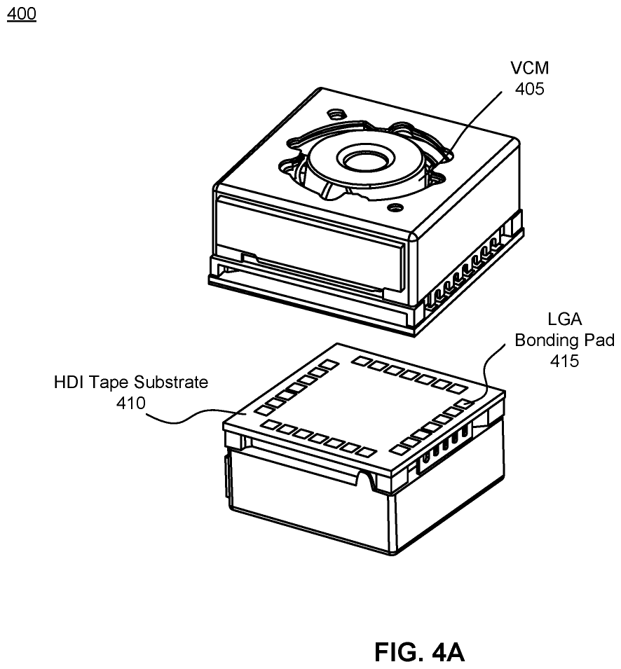

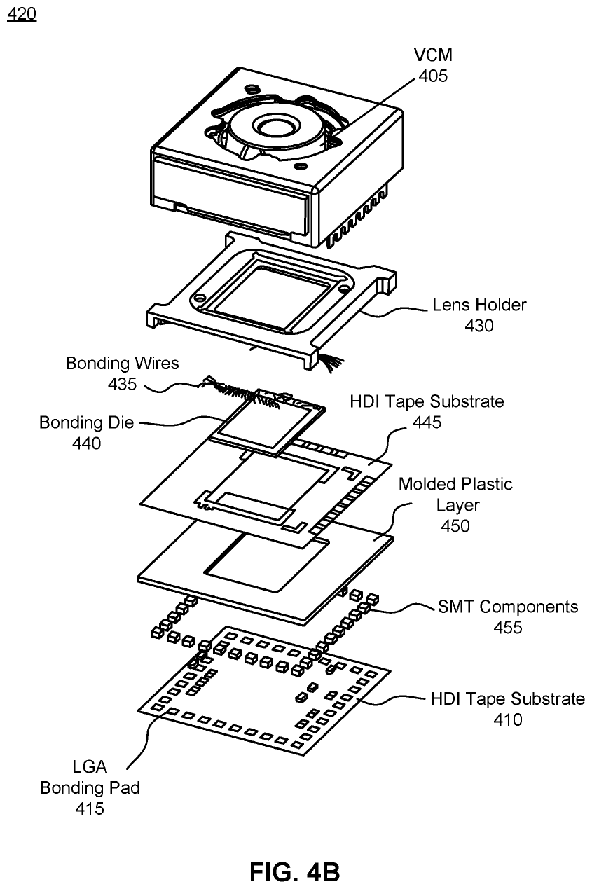

FIG. 4A illustrates an example expanded view 400 of the camera device packaged using the process 300. The camera device illustrated in FIG. 4A may include, among other components, a VCM 405, and a HDI tape substrate 410 with a land grid array (LGA) bonding pad 415. The camera device illustrated in FIG. 4A may include additional components not shown in FIG. 4A (e.g., as shown in FIG. 4B).

The VCM 405 may provide autofocus during image capture. The VCM 405 may include voice coil actuators that consist of a single-pole permanent magnet and a copper coil. The VCM 405 is a two-lead, single phase motor that does not require commutation, resulting in simple but effective autofocusing operation. The HDI tape substrate 410 may represent a bottom substrate of the camera device. As shown in FIG. 4A, the HDI tape substrate 410 may include the LGA bonding pad 415 for coupling various components to a top surface of the HDI tape substrate 410. More details about coupling the various components to the top surface of the HDI tape substrate 410 are provided below in relation to FIG. 4B.

FIG. 4B illustrates an example expanded view 420 of the camera device packaged using the process 300. As shown in FIG. 4B, in addition to the VCM 405 and the HDI tape substrate 410 (i.e., bottom surface) previously shown in FIG. 4A, the camera device may include a lens holder 430, a HDI tape substrate 445 (i.e., top substrate), a molded plastic layer 450, and SMT components 455. The camera device may include additional components not shown in FIG. 4B.

The lens holder 430 is a mechanical structure configured to hold a lens assembly. The lens holder 430 functions to couple the lens assembly to the HDI tape substrate 445. The lens holder 430 may include an aperture through which light from the lens assembly passes toward the image sensor. In some embodiments, the aperture of the lens holder 430 includes various filters, such as an infrared cut-off filter (IRCF) for blocking infrared light from the local area and propagate the visible light to the image sensor. The lens assembly held by the lens holder 430 represents a mechanical structure or housing for carrying one or more lenses. The lens assembly is a hollow structure with an opening on opposite ends of the lens assembly. The openings may provide a path for light (e.g., visible light, infrared light, etc.) to transmit between a local area and an image sensor of the camera device. Inside the lens assembly, one or more lenses may be positioned between the two openings. The lens assembly held by the lens holder 430 may be manufactured from a wide variety of materials ranging from plastic to metals. In some embodiments, one or more exterior surfaces of the lens assembly are coated with a polymer (e.g., a sub-micron thick polymer). The lens assembly held by the lens holder 430 may be rotationally symmetric about an optical axis of the one or more lenses of the lens assembly. In some embodiments, the lens assembly held by the lens holder 430 includes one or more actuators (e.g., voice coil motors, shape memory alloys, microelectromechanical systems (MEMS) devices, etc.) that translate one or more of the lenses along their optical axis to provide auto focus capability.

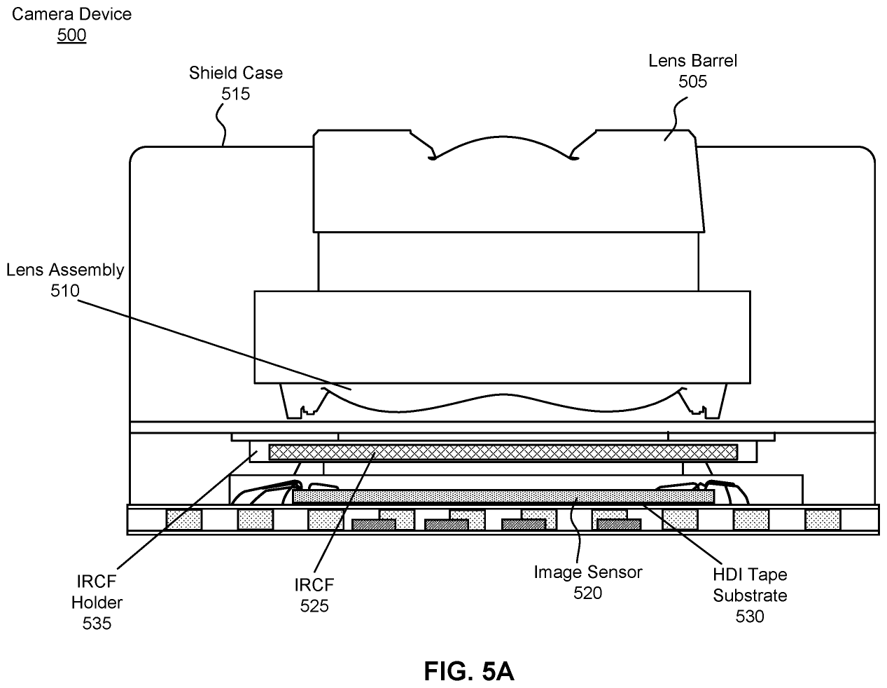

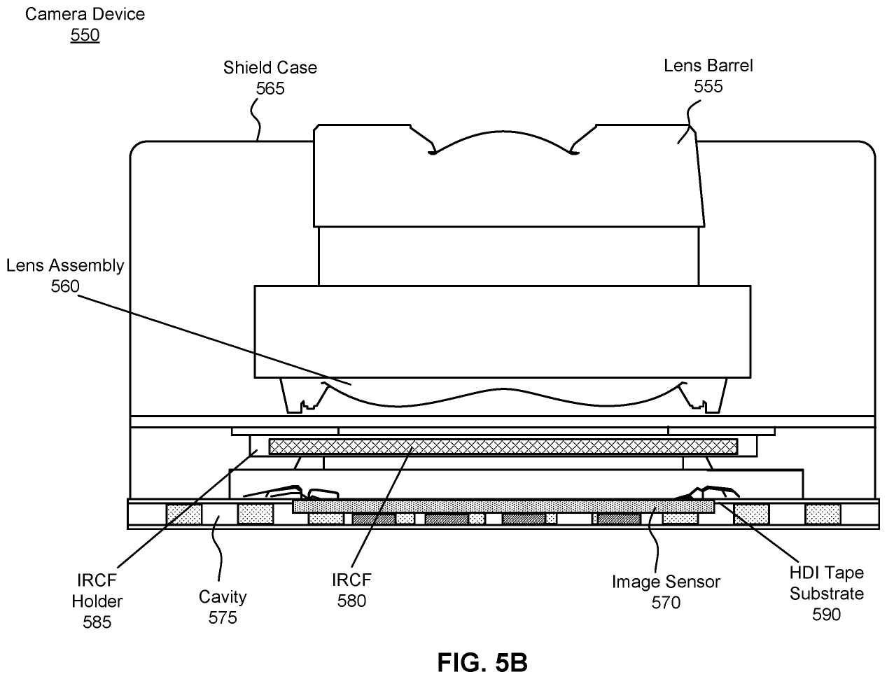

The HDI tape substrate 445 may represent a top substrate of the camera device. A top surface of the HDI tape substrate 445 may be coupled to the lens holder 430. In some embodiments, the HDI tape substrate 445 is formed such that the HDI tape substrate 445 includes a cavity within which the image sensor is located (e.g., as shown in FIG. 5B). In other embodiments, the image sensor is located on the top surface of the HDI tape substrate 445 (e.g., as shown in FIG. 5A). The HDI tape substrate 445 may include a plurality of electrodes, and at least some of the electrodes (e.g., data pathways, power, ground, etc.) may be coupled to the image sensor. Wires 435 and a die 440 (e.g., for integration of the image sensor) may be bonded onto the top surface of the HDI tape substrate 445.

As shown in FIG. 4B, the HDI tape substrate 410 may be coupled to a plurality of SMT components 455 mounted on the top surface of the HDI tape substrate 410, e.g., via the LGA bonding pad 415. The SMT components 455 may be, e.g., capacitors, resistors, EPROMs, etc. The HDI tape substrate 410 may include a plurality of electrodes, at least some of which are connected to the SMT components 455. One or more electrodes of the HDI tape substrate 410 may be also connected to one or more other components outside of the camera device (e.g., for data readout). Additionally, a plurality of pillars (not shown in FIG. 4B) may be mounted to the top surface of the HDI tape substrate 410. The pillars may be, e.g., positioned along a periphery of the top surface of the HDI tape substrate 410. At least some of the pillars may be connected to one or more electrodes of the HDI tape substrate 410. In some embodiments, one or more of the pillars are dummy pillars whose purpose is to provide structural support for the camera device.

The molded plastic layer 450 may be sandwiched between a bottom surface of the HDI tape substrate 445 and the top surface of the HDI tape substrate 410. The molded plastic layer 450 may include one or more vias to interconnect at least one electrode of the HDI tape substrate 445 to at least one electrode of the HDI tape substrate 410. In some embodiments, the one or more vias are the pillars that are connected to one or more electrodes of the HDI tape substrate 410. The pillars may connect to corresponding electrodes of the HDI tape substrate 445. In this manner, continuous circuits can be formed between the image sensor and the SMT components 455 on the HDI tape substrate 410, and other components outside of the camera device.

Although FIG. 4B illustrates a single molded plastic layer 450 placed between the HDI tape substrate 445 and the HDI tape substrate 410, in other embodiments, one or more additional HDI tape substrates and molded plastic layers may be added in a vertical stack. For example, there may be a third HDI tape substrate with a second molded plastic layer between the third HDI tape substrate and the HDI tape substrate 410. In this manner, additional components may be vertically integrated into the camera device.

FIG. 5A is a cross section of an example structure of a camera device 500 with an image sensor 520 located on a top surface of a HDI tape substrate 530, in accordance with one or more embodiments. The camera device 500 may be packaged into a wearable device (e.g., headset, smartwatch, etc.) using the process 300. The HDI tape substrate 530 may represent a top substrate of the camera device 500. The HDI tape substrate 530 may be an embodiment of the HDI tape substrate 445. In addition to the image sensor 520 and the HDI tape substrate 530, the camera device 500 includes a lens barrel 505, a lens assembly 510, a shield case 515, an IRCF 525, and an IRCF holder 535. In alternative configurations, different and/or additional components may be included in the camera device 500. For example, in some embodiments, the camera device 500 may include a controller (not shown in FIG. 5A). In alternative embodiments, the controller may be part of some other system (e.g., a wearable device the camera device 500 is integrated into).

The camera device 500 may be configured to have both a focusing assembly and a stabilization assembly (not shown in FIG. 5A). The focusing assembly is configured to cause a translation of the lens barrel 505 in a direction parallel to an optical axis of the lens assembly 510. The focusing assembly may provide an auto focus functionality for the camera device 500. The stabilization assembly may be configured to cause a translation of the lens barrel 505 in one or more directions perpendicular to the optical axis of the lens assembly 510. The stabilization assembly may provide an OIS functionality for the camera device 500 by stabilizing an image projected through the lens barrel 505 to the image sensor 520.

The lens barrel 505 is a mechanical structure or housing for carrying one or more lenses of the lens assembly 510. The lens barrel 505 is a hollow structure with an opening on opposite ends of the lens barrel 505. The openings may provide a path for light (e.g., visible light, infrared light, etc.) to transmit between a local area and the image sensor 520. Inside the lens barrel 505, one or more lenses of the lens assembly 510 are positioned between the two openings. The lens barrel 505 may be manufactured from a wide variety of materials ranging from plastic to metals. In some embodiments, one or more exterior surfaces of the lens barrel 505 are coated with a polymer (e.g., a sub-micron thick polymer). The lens barrel 505 may be rotationally symmetric about the optical axis of the lens assembly 510.

The shield case 515 may enclose some of the components of the camera device 500 as illustrated in FIG. 5A. In other embodiments (not shown), the shield case 515 encloses all of the components of the camera device 500. As illustrated in FIG. 5A, the shield case 515 partially encloses the lens barrel 505. The shield case 515 provides a space in which the lens barrel 505 can translate along the optical axis of the lens assembly 510 and/or translate in a direction perpendicular to the optical axis of the lens assembly 510. In some embodiments, the shield case 515 provides a space in which the lens barrel 505 rotates relative to one or more axes that are perpendicular to the optical axis of the lens assembly 510. In some embodiments, the shield case 515 may be rectangular-shaped. In alternative embodiments, the shield case 515 may be circular, square, hexagonal, or any other shape. In embodiments where the camera device 500 is part of a wearable device (e.g., headset, smartwatch), the shield case 515 may couple to (e.g., be mounted on, affixed to, attached to, etc.) another component of the wearable device, such as a frame of the wearable device. For example, the shield case 515 may be mounted on a frame (e.g., the frame 110) of the headset. The shield case 515 may be manufactured from a wide variety of materials ranging from plastic to metals. In some examples, the shield case 515 is manufactured from a same material as the material of the wearable device the shield case 515 is coupled to such that the shield case 515 is not distinguishable from the rest of the wearable device. In some embodiments, the shield case 515 is manufactured from a material that provides a magnetic shield to surrounding components of the electronic device. In these embodiments, the shield case 515 may be a shield can. In some embodiments, one or more interior surfaces of the shield case 515 are coated with a polymer similar to the lens barrel 505 described above.

The image sensor 520 captures data (e.g., one or more images) describing a local area. The image sensor 520 may include one or more individual sensors, e.g., a photodetector, a complementary metal-oxide semiconductor (CMOS) sensor, a charge-coupled device (CCD) sensor, some other device for detecting light, or some combination thereof. The individual sensors may be in an array. For the camera device 500 integrated into a wearable device, the local area is an area surrounding the wearable device. The image sensor 520 captures light from the local area. The image sensor 520 may capture visible light and/or infrared light from the local area surrounding the electronic device. The visible and/or infrared light is focused from the local area to the image sensor 520 via the lens barrel 505. The image sensor 520 may include various filters, such as the IRCF 525. The IRCF 525 is a filter configured to block the infrared light from the local area and propagate the visible light to the image sensor 520. The IRCF 525 may be placed within the IRCF holder 535. As shown in FIG. 5A, the image sensor 520 may be located on top of the HDI tape substrate 530. In some embodiments (not shown), a controller may be further located on the HDI tape substrate 530 and the HDI tape substrate 530 electrically connects the controller to various components of the camera device 500. In other embodiments (not shown), the controller is in a different location within the camera device 500 or external to the camera device 500.

FIG. 5B is a cross section of an example structure of a camera device 550 with an image sensor 570 located within a cavity 575 of a HDI tape substrate 590, in accordance with one or more embodiments. The camera device 550 may be packaged into a wearable device (e.g., headset, smartwatch, etc.) using the process 300. The HDI tape substrate 590 may represent a top substrate of the camera device 550. The HDI tape substrate 590 may be an embodiment of the HDI tape substrate 445. In addition to the image sensor 570 and the HDI tape substrate 590, the camera device 550 includes a lens barrel 555, a lens assembly 560, a shield case 565, an IRCF 580, and an IRCF holder 585. In alternative configurations, different and/or additional components may be included in the camera device 550. Each component of the camera device 550 operates in the substantially same manner as a corresponding component of the camera device 500. In comparison with packaging of the camera device 500, during the process 300 of packaging the camera device 550, the cavity 575 may be formed within the HDI tape substrate 590 for placing the image sensor 570 in between top and bottom surfaces of the HDI tape substrate 590.

### Soft Electrodes for Wearable Devices

Some embodiments of the present disclosure are directed to soft electrodes for integration into wearable devices. The wearable device may be, e.g., a smartwatch, a bracelet, a ring, a glove, a necklace, a piece of clothing, a headset (e.g., smart glasses, head-mounted display, etc.), or some combination thereof. The wearable device includes one or more soft electrodes and a controller. The wearable device may include portions that are made from soft materials. The soft materials may include, e.g., elastomers, fabrics, some other soft material, or some combination thereof.

FIG. 6 illustrates an example view 600 of a band 605 of a wearable device, in accordance with one or more embodiments. The band 605 may be, e.g., part of a smartwatch, bracelet, ring, etc. The band 605 may include one or more soft electrode regions 610. A soft electrode region 610 is a location on a wearable device that includes one or more soft electrodes 615. As shown in FIG. 6 there may be two soft electrodes 615 in the soft electrode region 610, but in other embodiments, there may be more or less soft electrodes. While not shown in FIG. 6, the band 605 may also include and/or be coupled to a controller.

The soft electrodes 615 may be configured to monitor electrical signals from a wearer (i.e., user) of the wearable device. A soft electrode 615 may include a conductive coating applied to an elastomer substrate. The elastomer substrate of the soft electrode 615 may provide a flexible and soft material base for the conductive coating. The elastomer substrate may be, e.g., nitrile rubber, butyl rubber, polybutadiene rubber, synthetic polyisoprene, neoprene, silicone, polyacylic, polyether block amides, ethylene-vinyl acetate, fluoroelastomer (FKM), thermoplastic polyurethane (TPU), some other flexible and soft material base, or some combination thereof. Properties of the elastomer substrate may include, e.g., hardness equal or below 100 when measured by a durometer, elongation up to 1000%, and the Young's modulus of approximately 3 MPa at ambient temperatures, or some combination thereof. The elastomer substrate may also include other additives to enhance conductivity, UV stability or chemical stability etc. under different use cases. The elastomer substrate may be conductive, non-conductive, or some combination thereof.

The conductive coating of the soft electrode 615 may be configured to detect one or more electrical signals from the wearer of the wearable device. The conductive coating may be a biocompatible material that either does not interact with a human body or does not elicit any undesirable local or systematic effect to a human body. The conductive inorganic coating may be, e.g., diamond like carbon (DLC, contains carbon and hydrogen), tetrahedral amorphous carbon (ta-C, pure carbon), nitrides (such as titanium carbon nitride or chromium nitride, etc.), or some combination thereof. The resistivity of these conductive coating materials can range from μOhm.cm to kOhm.cm.

In some embodiments, in addition to pads for the soft electrodes 615, the conductive coating is used to form traces to conduct an electrical current to other electrodes, vias, a bus, a controller, some other electrical component (e.g., flexible electronics), or some combination thereof. The coated electrodes may also be connected to other electrical components through conductive adhesives such as liquid silicone conductive adhesive (e.g., DOWSIL™ EC-6601). FIG. 7 illustrates an example view 700 of multiple soft electrodes 705 coupled to a common bus 710 that may be integrated within a wearable device, in accordance with one or more embodiments. Each soft electrode 705 may be an embodiment of the soft electrode 615. A controller (not shown in FIG. 7) may be coupled to the soft electrodes 705 for collecting electrical signals detected by the soft electrodes 705 that are communicated to the controller via the common bus 710.

Referring back to FIG. 6, the flexibility and softness of the elastomer substrate of the soft electrode 615 may function to mitigate discomfort of the soft electrode 615 being placed in contact with skin of the wearer of the band 605. Likewise, the conductive coating of the soft electrode 615 may be biocompatible to mitigate irritation of the wearer's skin. In contrast, other conductive elastomers typically has conductive fillers (e.g., graphite, Ag nanowires, carbon nanotubes, etc.), which can often have challenge to be uniformly disbursed in the elastomer resulting in uneven distribution (i.e., uneven conductivity), and moreover nanowires can irate the wearer's skin if without encapsulation (i.e., may have biocompatibility issues). Other conductive elastomers may also have issues such as collecting dust and dirt over wear, which may impact the sensing performance.

During manufacture, the conductive coating of the soft electrode 615 may be applied to a surface of the elastomer substrate via, e.g., filtered cathodic vacuum arcing (FCVA). Other deposition technologies such as PVD, chemical vapor deposition (CVD), or variations of these technologies are also feasible. In some embodiments, the elastomer substrate is plasma treated prior to applying the conductive coating to improve bonding of the coated layer to the elastomer substrate. One or more properties of the conductive coating layer may be tuned. For example, in embodiments where the coating material is DLC, conductivity and/or hardness of the DLC may be adjusted using, e.g., sp2 layer hybridization and/or sp3 layer hybridization to target conductivity and/or hardness values. In some embodiments, the conductive coating layer of the soft electrode 615 has one or more overcoats such that the DLC layer would not be directly in contact with the wearer's skin. In other embodiments, the soft electrode 615 is configured such that the DLC coating would be in direct contact with the wearer's skin.

The controller coupled to the band 605 may control components of the wearable device. The controller may be electrically coupled to the one or more soft electrodes 615. In some embodiments, the controller may be electrically coupled to one or more pairs of the soft electrodes 615. The controller may perform electromyography (EMG) signal collection using one or more electrical signals from the one or more soft electrodes 615. The EMG signals may be used to, e.g., detect pose of a body part controlled by muscles generating the one or more electrical signals. The controller may determine the pose using a model (e.g., machine learned model) that maps detected electrical signals to specific poses. The controller may perform an action based on the detected pose. For example, the detected pose may correspond to a particular command (e.g., turn on/off, adjust volume, etc.). Likewise, the pose may be used in artificial reality applications, e.g., to facilitate interacting with a virtual object.

### Solar Heat Reflective and Device Radiative Aesthetic Layered Coating

Some embodiments of the present disclosure are directed to a process for coating of a wearable device (e.g., headset). A coating (e.g., aggregate coating) applied to the wearable device may present as a particular color, and may have an increased reflective cooling for solar flux (e.g., UV into NIR), while having high emissivity in the mid-to-far IR (e.g., heat emitted by the wearable device). In some embodiments, a substrate (e.g., a frame of the wearable device) is coated via PVD or CVD with one or more thin films that are reflective to solar flux and have high emissivity for lower wavelengths. A second ‘color’ coating (e.g., paint) may be applied over the one or more thin films to create an aggregate coating. The second coating may be configured (e.g., via embedding particles) to absorb and/or scatter light in certain bands while being transparent to light outside those bands. In other embodiments, the substrate is composed of UHMWPE (e.g., for solar reflectivity), and is then coated with an UV/IR transparent tint coating (e.g., for aesthetics) to form the aggregate coating.

The aggregate coating described herein may be designed such that its emissivity (or reflectivity) is tuned over the electromagnetic spectrum to achieve multiple objectives. First, the aggregate coating may minimize emissivity in the UV to NIR band (e.g., 0.2 μm-3.0 μm) to minimize absorption of solar energy that yields undesirable heating of a surface of a wearable device (e.g., frame surface). Second, the aggregate coating may maximize the emissivity in the mid-to-far IR band (e.g., 3.0 μm-30.0 μm) to enable re-radiation from the surface to deep space through the atmospheric transmission window, thereby reducing a temperature of the surface. Lastly, the emissivity profile of the aggregate coating may be tuned to provide a target aesthetic color (e.g., blue, green, black, etc.). The target color may be achieved via an addition of spectral notching in the visible band (e.g., 0.3 μm-0.8 μm). The aggregate coating may be designed as a balance of aesthetic, thermal requirements (they compete in the visible spectrum), and robustness.

FIG. 8A illustrates an example graph 800 of spectral emissivity for black coating of a wearable device (e.g., headset), in accordance with one or more embodiments. FIG. 8B illustrates an example graph 810 of spectral emissivity for green coating of a wearable device (e.g., headset), in accordance with one or more embodiments. Although the spectral emissivity only for black and green coatings are shown in FIG. 8A and FIG. 8B, the technique presented herein holds for any desired coating color/aesthetic. It can be observed from FIG. 8A and FIG. 8B that, for the typical solar flux and idealized black and green coatings, the re-radiation in space within the mid-to-far IR band (e.g., between 3.0 μm and 30.0 μm) can be substantial, thus reducing a temperature of a surface of the wearable device (e.g., frame surface) exposed to the solar flux. The impact of the aesthetic solar coating presented herein may have a substantial impact on reduction of a temperature of the surface of the wearable device when the surface is exposed to the solar flux. The temperature reduction of the surface of the wearable device may directly translate to additional capabilities in consumer and mobile devices in outdoor environments, improving the user experience for such wearable devices.

The aggregate coating for a wearable device presented herein may be a (i) solar reflecting coating, that (ii) achieves a specific aesthetic target, that (iii) is mechanically robust, and (iv) suitable for application at high volume. A non-exhaustive list of technologies for generating the aggregate coating is provided below. These technologies are not stand-alone and can be combined to improve performance as necessary. While many of the techniques have been developed for separate purposes, they have not been combined into a multi-purpose coating structure to address solar heating, radiative cooling, and product appearance.

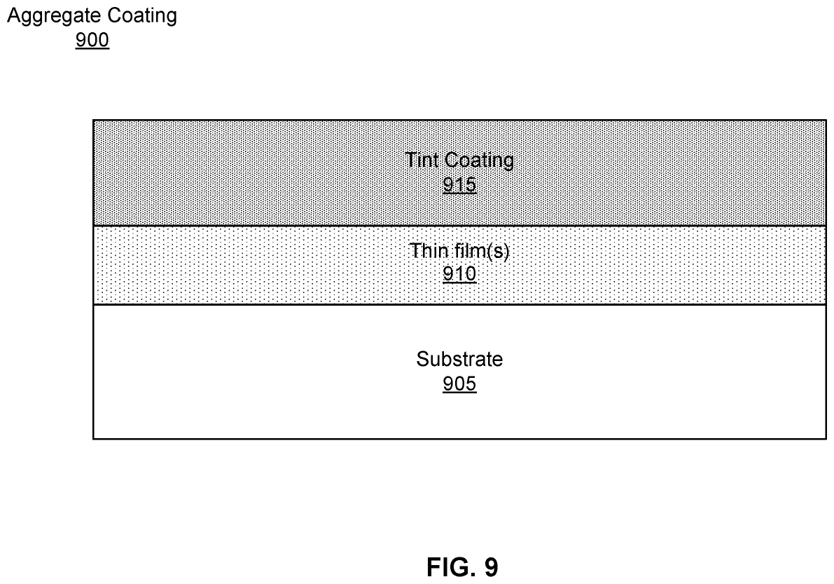

FIG. 9 illustrates an example aggregate coating 900, in accordance with one or more embodiments. The aggregate coating 900 may comprise a substrate 905, one or more thin films 910, and a tint coating 915. The substrate 905 may be, e.g., plastic, metal, UHMWPE, some other suitable material, or some combination thereof. One potential advantage of UHMWPE is that in addition to having good mechanical and thermal properties, UHMWPE can be tuned to have a very high solar reflectance. The substrate 905 may be part of a wearable device (e.g., the frame 110 of the headset 100).

The one or more thin films 910 may be applied to the substrate 905. The one or more thin films 910 may be applied via, e.g., PVD and/or CVD. The one or more thin films 910 may be, e.g., oxide, Germanium, Indium, Silicon, Tin, etc. The one or more thin films 910 may have a total thickness of 5 μm or less. For example, the one or more thin films 910 may have a total depth of 2 μm. The one or more thin films 910 may be configured to mitigate emissivity in the UV to NIR band, and to increase the emissivity in the mid-to-far IR band. In some embodiments, the one or more thin films 910 may be selected to help facilitate tuning the emissivity profile of the aggregate coating 900 to provide a target aesthetic color (e.g., blue, green, black, etc.).

The tint coating 915 may be applied over the one or more thin films 910 to form the aggregate coating 900. The tint coating 915 may be a cosmetic purpose color coating (e.g., spay, dip, flow, etc.) The tint coating 915 may be substantially thicker than the one or more thin films 910. For example, the tint coating 915 may be approximately 20 μm thick, and the one or more thin films 910 may be, e.g., 2 μm thick. The tint coating 915 may be configured to absorb and/or scatter (e.g., via embedding particles) light in certain visible bands (e.g., to establish a color the coated substrate presents as) while being transparent to light outside those bands. In this manner, the aggregate coating 900 may have an emissivity distribution in the UV and NIR bands that is lower than an emissivity distribution in the visible band, and the emissivity distribution in the visible band may be lower than an emissivity distribution in the mid-to-far IR band. Note that this may depend on some degree on a target aesthetic color. For example, if the target aesthetic color is a dark black, it may be possible for the emissivity in the visible band to be similar, or even higher, than the emissivity in the mid-to-far IR band.

The aggregate coating may be formed from one or more heat reflective paints. Paint is one of the easiest and scalable solutions to achieve target colors in products. Here, special pigments may be utilized in the paint to selectively absorb the light photons in the visible band. To be more specific, the color black may be achieved by absorbing all photons in the visible band. In contrast, commercial off-the-shelf paint and resins have carbon black that absorbs wavelengths from UV to mid-IR bands. If the pigments in the paint are made to be transmitting in the IR band, then an intermediate coat can be leveraged to scatter/reflect the IR light. For example, in some embodiments, the pigments may be TiO₂ particles, and sizing of the particles may be chosen to obtain a specific color/emissivity (e.g., reflect blue light that is of high energy).

In some embodiments (not shown in FIG. 9), an additional UV/IR transparent tint coating is applied over the tint coating 915 to further enhance aesthetic appearance of the aggregate coating 900. In some embodiments, the substrate 905 is composed of UHMWPE, and an UV/IR transparent tint coating (not shown in FIG. 9) is applied directly to the UHMWPE to form the aggregate coating 900. In this embodiment, the UHMWPE provides the functionality (e.g., solar reflectivity) of the one or more thin films 910, and the UV/IR transparent tint coating provides the functionality (e.g., color) of the tint coating 915. In some embodiments, the UHMWPE can be a single film with the thickness greater than 5 μm (e.g., 10 μm, 25 μm, 50 μm, etc.). Alternatively, the UHMWPE may be a stack of compressed UHMWPE films with a total thickness greater than 500 μm (e.g., 1 mm, 5 mm, 10 mm, etc.). In some embodiments, the UHMWPE is laminated on polyvinylidene fluoride (PVDF) or PVC to increase the emissivity in the long wavelength infrared (e.g., between 8 μm and 14 μm) and hence re-radiation to space. The PVDF or PVC can be in the form of film, porous film, fiber-film, some other type of film, or combination thereof.

In some embodiments, a method of coating a wearable device (e.g., the headset 100) is presented herein. One or more thin films (e.g., the one or more thin films 910) may be applied to a surface of the wearable device (e.g., the substrate 905 or the frame 110 of the headset 100). A paint coating (e.g., the tint coating 915) may be then applied to a surface of the one or more thin films to form an aggregate coating (e.g., the aggregate coating 900). The aggregate coating may have an emissivity distribution that includes an UV band, a NIR band, a visible band, and a mid-to-far IR band. The emissivity distribution in the UV and NIR bands may be lower than the emissivity distribution in the visible band, and the emissivity distribution in the visible band may be lower than the emissivity distribution in the mid-to-far IR band. The aggregate coating may present as a target color, and heat generated by the wearable device in the mid-to-far IR band may be substantially absorbed and re-radiated.

The frame 110 of the headset 100 may be coated with the aggregate coating 900 that represents a solar heat reflective and device radiative aesthetic coating. The aggregate coating 900 of the frame 110 may have an emissivity of a first average value over an UV band of radiation and a NIR band of radiation that is low (e.g., close to zero). The aggregate coating 900 of the frame 110 may also have an emissivity of a second average value over a visible band of radiation. The emissivity over the visible band of radiation may be such that aggregate coating 900 appears as a particular (target) color. The aggregate coating 900 of the frame 110 may have an emissivity of a third average value for a band of radiation in the mid-to-far infrared. The emissivity over the band of radiation in the mid-to-far infrared may be relatively high (e.g., close to 1). The first average value may be less than the second average value, and the second average value may be less than the third average value. In this manner, incident radiation in the UV and the NIR bands may be substantially reflected by the aggregate coating 900. Incident radiation in the visible band may be such that the aggregate coating 900 of the frame 110 appears having a target color. Heat generated in the mid-to-far IR band by active components (e.g., DCA, display elements, audio system, etc.) of the headset 100 may be substantially absorbed and re-radiated away from the headset 100. The paint coating (e.g., the tint coating 915) may absorb and scatter light in the visible band while propagating light outside of the visible band. A plurality of pigments may be included in the paint coating (e.g., the tint coating 915) to selectively absorb and scatter light in the visible band.

### Process Flow

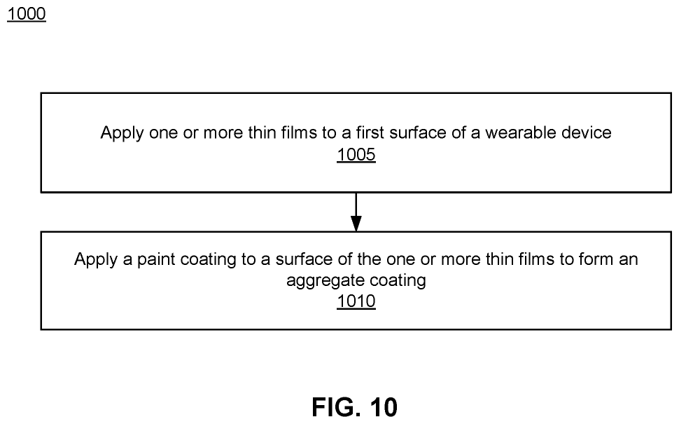

FIG. 10 is a flowchart illustrating a process 1000 for coating of a wearable device (e.g., headset), in accordance with one or more embodiments. The process 1000 shown in FIG. 10 may be performed by a manufacturing system. Other entities may perform some or all of the steps in FIG. 10 in other embodiments. Embodiments may include different and/or additional steps, or perform the steps in different orders.

The manufacturing system applies 1005 one or more thin films to a first surface of the wearable device. The manufacturing system applies 1010 a paint coating to a surface of the one or more thin films to form an aggregate coating. The paint coating may absorb and scatter light in the visible band while propagating light outside of the visible band. A plurality of pigments in the paint coating may be applied to selectively absorb and scatter light in the visible band.

The aggregate coating may have an emissivity distribution that includes an UV band, a NIR band, a visible band, and a mid-to-far IR band. The emissivity distribution in the UV and NIR bands may be lower than the emissivity distribution in the visible band, and the emissivity distribution in the visible band may be lower than the emissivity distribution in the mid-to-far IR band.

The aggregate coating may reflect incident radiation in the UV and NIR bands. Incident radiation may be radiated in the visible band such that the aggregate coating appears as a target color. Heat generated by the wearable device in the mid-to-far IR band may be absorbed and re-radiated.

In some embodiments, a wearable device (e.g., headset) is described herein that comprises one or more soft electrode and a controller. Each of the one or more soft electrodes may comprise a conductive material applied to an elastomer substrate. The one or more soft electrode may monitor one or more electrical signals generated by a wearer of the wearable device. The controller may be configured to perform an action based in part on the monitored electrical signals. One or more overcoats may be applied on the conductive coating such that the conductive coating is not in direct contact with a skin of the wearer.

In some embodiments, a camera device is packaged for integration into a wearable device (e.g., smartwatch, headset, etc.). The camera device may include an image sensor, a lens assembly configured to hold at least one lens, a first HDI tape substrate having a top surface and a bottom surface, a second HDI tape substrate, and a molded plastic layer. The top surface of the first HDI tape substrate may be coupled to the lens assembly, the first HDI tape substrate may be coupled to the image sensor, and the first HDI tape substrate may include a first plurality of electrodes. The second HDI tape substrate may include a second plurality of electrodes and a plurality of SMT components mounted on a top surface of the second HDI tape substrate. The molded plastic layer may be sandwiched between the bottom surface of the first HDI tape substrate and the top surface of the second HDI tape substrate. The molded plastic layer may include one or more vias to interconnect at least one electrode of the first plurality of electrodes to at least one electrode of the second plurality of electrodes.

The first HDI tape substrate includes a cavity within which the image sensor is located. Alternatively, the image sensor may be located on the top surface of the first HDI tape substrate. One or more electrodes of the first plurality of electrodes may be coupled to the image sensor. One or more electrodes of the second plurality of electrodes may be connected to the SMT components. One or more pillars may be mounted to the top surface of the second HDI tape substrate. The one or more pillars may be positioned along a periphery of the top surface of the second HDI tape substrate. At least one pillar of the one or more pillars may be connected to at least one electrode of the second plurality of electrodes. At least one pillar of the one or more pillars may comprise the one or more vias connected to one or more electrodes of the second plurality of electrodes.

### System Environment

FIG. 11 is a system 1100 that includes a headset 1105, in accordance with one or more embodiments. In some embodiments, the headset 1105 may be the headset 100 of FIG. 1A or the headset 105 of FIG. 1B. The system 1100 may operate in an artificial reality environment (e.g., a virtual reality environment, an augmented reality environment, a mixed reality environment, or some combination thereof). The system 1100 shown by FIG. 11 includes the headset 1105, an input/output (I/O) interface 1110 that is coupled to a console 1115, the network 1120, and the mapping server 1125. While FIG. 11 shows an example system 1100 including one headset 1105 and one I/O interface 1110, in other embodiments any number of these components may be included in the system 1100. For example, there may be multiple headsets each having an associated I/O interface 1110, with each headset and I/O interface 1110 communicating with the console 1115. In alternative configurations, different and/or additional components may be included in the system 1100. Additionally, functionality described in conjunction with one or more of the components shown in FIG. 11 may be distributed among the components in a different manner than described in conjunction with FIG. 11 in some embodiments. For example, some or all of the functionality of the console 1115 may be provided by the headset 1105. A frame of the headset 1105 may be implemented as a solar heat reflective and device radiative aesthetic coating, e.g., as described above in relation to FIGS. 8A through 10.

The headset 1105 includes a display assembly 1130, an optics block 1135, one or more position sensors 1140, a DCA 1145, and an audio system 1150. Some embodiments of headset 1105 have different components than those described in conjunction with FIG. 11. Additionally, the functionality provided by various components described in conjunction with FIG. 11 may be differently distributed among the components of the headset 1105 in other embodiments, or be captured in separate assemblies remote from the headset 1105.

The display assembly 1130 displays content to the user in accordance with data received from the console 1115. The display assembly 1130 displays the content using one or more display elements (e.g., the display elements 120). A display element may be, e.g., an electronic display. In various embodiments, the display assembly 1130 comprises a single display element or multiple display elements (e.g., a display for each eye of a user). Examples of an electronic display include: a liquid crystal display (LCD), an organic light emitting diode (OLED) display, an active-matrix organic light-emitting diode display (AMOLED), a waveguide display, some other display, or some combination thereof. Note in some embodiments, the display element 120 may also include some or all of the functionality of the optics block 1135.

The optics block 1135 may magnify image light received from the electronic display, corrects optical errors associated with the image light, and presents the corrected image light to one or both eye boxes of the headset 1105. In various embodiments, the optics block 1135 includes one or more optical elements. Example optical elements included in the optics block 1135 include: an aperture, a Fresnel lens, a convex lens, a concave lens, a filter, a reflecting surface, or any other suitable optical element that affects image light. Moreover, the optics block 1135 may include combinations of different optical elements. In some embodiments, one or more of the optical elements in the optics block 1135 may have one or more coatings, such as partially reflective or anti-reflective coatings.

Magnification and focusing of the image light by the optics block 1135 allows the electronic display to be physically smaller, weigh less, and consume less power than larger displays. Additionally, magnification may increase the field of view of the content presented by the electronic display. For example, the field of view of the displayed content is such that the displayed content is presented using almost all (e.g., approximately 110 degrees diagonal), and in some cases, all of the user's field of view. Additionally, in some embodiments, the amount of magnification may be adjusted by adding or removing optical elements.

In some embodiments, the optics block 1135 may be designed to correct one or more types of optical error. Examples of optical error include barrel or pincushion distortion, longitudinal chromatic aberrations, or transverse chromatic aberrations. Other types of optical errors may further include spherical aberrations, chromatic aberrations, or errors due to the lens field curvature, astigmatisms, or any other type of optical error. In some embodiments, content provided to the electronic display for display is pre-distorted, and the optics block 1135 corrects the distortion when it receives image light from the electronic display generated based on the content.

The position sensor 1140 is an electronic device that generates data indicating a position of the headset 1105. The position sensor 1140 generates one or more measurement signals in response to motion of the headset 1105. The position sensor 190 is an embodiment of the position sensor 1140. Examples of a position sensor 1140 include: one or more IMUs, one or more accelerometers, one or more gyroscopes, one or more magnetometers, another suitable type of sensor that detects motion, or some combination thereof. The position sensor 1140 may include multiple accelerometers to measure translational motion (forward/back, up/down, left/right) and multiple gyroscopes to measure rotational motion (e.g., pitch, yaw, roll). In some embodiments, an IMU rapidly samples the measurement signals and calculates the estimated position of the headset 1105 from the sampled data. For example, the IMU integrates the measurement signals received from the accelerometers over time to estimate a velocity vector and integrates the velocity vector over time to determine an estimated position of a reference point on the headset 1105. The reference point is a point that may be used to describe the position of the headset 1105. While the reference point may generally be defined as a point in space, however, in practice the reference point is defined as a point within the headset 1105.

The DCA 1145 generates depth information for a portion of the local area. The DCA includes one or more imaging devices and a DCA controller. The DCA 1145 may also include an illuminator. Operation and structure of the DCA 1145 is described above in relation to FIG. 1A. A process of packaging an imaging device of the DCA 1145 is described above in relation to FIGS. 3 through 5B.

The audio system 1150 provides audio content to a user of the headset 1105. The audio system 1150 is substantially the same as the audio system 200 described above. The audio system 1150 may comprise one or acoustic sensors, one or more transducers, and an audio controller. The audio system 1150 may provide spatialized audio content to the user. In some embodiments, the audio system 1150 may request acoustic parameters from the mapping server 1125 over the network 1120. The acoustic parameters describe one or more acoustic properties (e.g., room impulse response, a reverberation time, a reverberation level, etc.) of the local area. The audio system 1150 may provide information describing at least a portion of the local area from e.g., the DCA 1145 and/or location information for the headset 1105 from the position sensor 1140. The audio system 1150 may generate one or more sound filters using one or more of the acoustic parameters received from the mapping server 1125, and use the sound filters to provide audio content to the user.

The I/O interface 1110 is a device that allows a user to send action requests and receive responses from the console 1115. An action request is a request to perform a particular action. For example, an action request may be an instruction to start or end capture of image or video data, or an instruction to perform a particular action within an application. The I/O interface 1110 may include one or more input devices. Example input devices include: a keyboard, a mouse, a game controller, or any other suitable device for receiving action requests and communicating the action requests to the console 1115. An action request received by the I/O interface 1110 is communicated to the console 1115, which performs an action corresponding to the action request. In some embodiments, the I/O interface 1110 includes an IMU that captures calibration data indicating an estimated position of the I/O interface 1110 relative to an initial position of the I/O interface 1110. In some embodiments, the I/O interface 1110 may provide haptic feedback to the user in accordance with instructions received from the console 1115. For example, haptic feedback is provided when an action request is received, or the console 1115 communicates instructions to the I/O interface 1110 causing the I/O interface 1110 to generate haptic feedback when the console 1115 performs an action.

The console 1115 provides content to the headset 1105 for processing in accordance with information received from one or more of: the DCA 1145, the headset 1105, and the I/O interface 1110. In the example shown in FIG. 11, the console 1115 includes an application store 1155, a tracking module 1160, and an engine 1165. Some embodiments of the console 1115 have different modules or components than those described in conjunction with FIG. 11. Similarly, the functions further described below may be distributed among components of the console 1115 in a different manner than described in conjunction with FIG. 11. In some embodiments, the functionality discussed herein with respect to the console 1115 may be implemented in the headset 1105, or a remote system.

The application store 1155 stores one or more applications for execution by the console 1115. An application is a group of instructions, that when executed by a processor, generates content for presentation to the user. Content generated by an application may be in response to inputs received from the user via movement of the headset 1105 or the I/O interface 1110. Examples of applications include: gaming applications, conferencing applications, video playback applications, or other suitable applications.

The tracking module 1160 tracks movements of the headset 1105 or of the I/O interface 1110 using information from the DCA 1145, the one or more position sensors 1140, or some combination thereof. For example, the tracking module 1160 determines a position of a reference point of the headset 1105 in a mapping of a local area based on information from the headset 1105. The tracking module 1160 may also determine positions of an object or virtual object. Additionally, in some embodiments, the tracking module 1160 may use portions of data indicating a position of the headset 1105 from the position sensor 1140 as well as representations of the local area from the DCA 1145 to predict a future location of the headset 1105. The tracking module 1160 provides the estimated or predicted future position of the headset 1105 or the I/O interface 1110 to the engine 1165.

The engine 1165 executes applications and receives position information, acceleration information, velocity information, predicted future positions, or some combination thereof, of the headset 1105 from the tracking module 1160. Based on the received information, the engine 1165 determines content to provide to the headset 1105 for presentation to the user. For example, if the received information indicates that the user has looked to the left, the engine 1165 generates content for the headset 1105 that mirrors the user's movement in a virtual local area or in a local area augmenting the local area with additional content. Additionally, the engine 1165 performs an action within an application executing on the console 1115 in response to an action request received from the I/O interface 1110 and provides feedback to the user that the action was performed. The provided feedback may be visual or audible feedback via the headset 1105 or haptic feedback via the I/O interface 1110.

The network 1120 couples the headset 1105 and/or the console 1115 to the mapping server 1125. The network 1120 may include any combination of local area and/or wide area networks using both wireless and/or wired communication systems. For example, the network 1120 may include the Internet, as well as mobile telephone networks. In one embodiment, the network 1120 uses standard communications technologies and/or protocols. Hence, the network 1120 may include links using technologies such as Ethernet, 802.11, worldwide interoperability for microwave access (WiMAX), 2G/3G/4G mobile communications protocols, digital subscriber line (DSL), asynchronous transfer mode (ATM), InfiniBand, PCI Express Advanced Switching, etc. Similarly, the networking protocols used on the network 1120 can include multiprotocol label switching (MPLS), the transmission control protocol/Internet protocol (TCP/IP), the User Datagram Protocol (UDP), the hypertext transport protocol (HTTP), the simple mail transfer protocol (SMTP), the file transfer protocol (FTP), etc. The data exchanged over the network 1120 can be represented using technologies and/or formats including image data in binary form (e.g., Portable Network Graphics (PNG)), hypertext markup language (HTML), extensible markup language (XML), etc. In addition, all or some of links can be encrypted using conventional encryption technologies such as secure sockets layer (SSL), transport layer security (TLS), virtual private networks (VPNs), Internet Protocol security (IPsec), etc.

The mapping server 1125 may include a database that stores a virtual model describing a plurality of spaces, wherein one location in the virtual model corresponds to a current configuration of a local area of the headset 1105. The mapping server 1125 receives, from the headset 1105 via the network 1120, information describing at least a portion of the local area and/or location information for the local area. The user may adjust privacy settings to allow or prevent the headset 1105 from transmitting information to the mapping server 1125. The mapping server 1125 determines, based on the received information and/or location information, a location in the virtual model that is associated with the local area of the headset 1105. The mapping server 1125 determines (e.g., retrieves) one or more acoustic parameters associated with the local area, based in part on the determined location in the virtual model and any acoustic parameters associated with the determined location. The mapping server 1125 may transmit the location of the local area and any values of acoustic parameters associated with the local area to the headset 1105.

One or more components of system 1100 may contain a privacy module that stores one or more privacy settings for user data elements. The user data elements describe the user or the headset 1105. For example, the user data elements may describe a physical characteristic of the user, an action performed by the user, a location of the user of the headset 1105, a location of the headset 1105, HRTFs for the user, etc. Privacy settings (or “access settings”) for a user data element may be stored in any suitable manner, such as, for example, in association with the user data element, in an index on an authorization server, in another suitable manner, or any suitable combination thereof.

A privacy setting for a user data element specifies how the user data element (or particular information associated with the user data element) can be accessed, stored, or otherwise used (e.g., viewed, shared, modified, copied, executed, surfaced, or identified). In some embodiments, the privacy settings for a user data element may specify a “blocked list” of entities that may not access certain information associated with the user data element. The privacy settings associated with the user data element may specify any suitable granularity of permitted access or denial of access. For example, some entities may have permission to see that a specific user data element exists, some entities may have permission to view the content of the specific user data element, and some entities may have permission to modify the specific user data element. The privacy settings may allow the user to allow other entities to access or store user data elements for a finite period of time.

The privacy settings may allow a user to specify one or more geographic locations from which user data elements can be accessed. Access or denial of access to the user data elements may depend on the geographic location of an entity who is attempting to access the user data elements. For example, the user may allow access to a user data element and specify that the user data element is accessible to an entity only while the user is in a particular location. If the user leaves the particular location, the user data element may no longer be accessible to the entity. As another example, the user may specify that a user data element is accessible only to entities within a threshold distance from the user, such as another user of a headset within the same local area as the user. If the user subsequently changes location, the entity with access to the user data element may lose access, while a new group of entities may gain access as they come within the threshold distance of the user.

The system 1100 may include one or more authorization/privacy servers for enforcing privacy settings. A request from an entity for a particular user data element may identify the entity associated with the request and the user data element may be sent only to the entity if the authorization server determines that the entity is authorized to access the user data element based on the privacy settings associated with the user data element. If the requesting entity is not authorized to access the user data element, the authorization server may prevent the requested user data element from being retrieved or may prevent the requested user data element from being sent to the entity. Although this disclosure describes enforcing privacy settings in a particular manner, this disclosure contemplates enforcing privacy settings in any suitable manner.

### Additional Configuration Information

The foregoing description of the embodiments has been presented for illustration; it is not intended to be exhaustive or to limit the patent rights to the precise forms disclosed. Persons skilled in the relevant art can appreciate that many modifications and variations are possible considering the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. A camera device comprising:
an image sensor;
a lens assembly configured to hold at least one lens;
a first high density interconnect (HDI) tape substrate having a top surface and a bottom surface, the top surface of the first HDI tape substrate coupled to the lens assembly, the first HDI tape substrate coupled to the image sensor, the first HDI tape substrate including a first plurality of electrodes;
a second HDI tape substrate including a second plurality of electrodes and a plurality of components mounted on a top surface of the second HDI tape substrate; and
a molded plastic layer sandwiched between the bottom surface of the first HDI tape substrate and the top surface of the second HDI tape substrate, the molded plastic layer including one or more vias to interconnect at least one electrode of the first plurality of electrodes to at least one electrode of the second plurality of electrodes.

2. The camera device of claim 1, wherein the first HDI tape substrate includes a cavity within which the image sensor is located.

3. The camera device of claim 1, wherein the image sensor is located on the top surface of the first HDI tape substrate.

4. The camera device of claim 1, wherein one or more electrodes of the first plurality of electrodes are coupled to the image sensor.

5. The camera device of claim 1, wherein one or more electrodes of the second plurality of electrodes are connected to the components.

6. The camera device of claim 1, further comprising:
one or more pillars mounted to the top surface of the second HDI tape substrate.

7. The camera device of claim 6, wherein the one or more pillars are positioned along a periphery of the top surface of the second HDI tape substrate.

8. The camera device of claim 6, wherein at least one pillar of the one or more pillars is connected to at least one electrode of the second plurality of electrodes.

9. The camera device of claim 6, wherein at least one pillar of the one or more pillars comprises the one or more vias connected to one or more electrodes of the second plurality of electrodes.

10. A wearable device comprising:
a soft electrode comprising a conductive coating applied to an elastomer substrate, the soft electrode configured to monitor one or more electrical signals generated by a wearer of the wearable device; and
a controller configured to perform an action based in part on the monitored one or more electrical signals.

11. The wearable device of claim 10, wherein the elastomer substrate is composed of at least one of: a nitrile rubber, a butyl rubber, a polybutadiene rubber, a synthetic polyisoprene, a neoprene, a silicone, a polyacylic, a polyether block amides, am ethylene-vinyl acetate, a fluoroelastomer, and a thermoplastic polyurethane.

12. The wearable device of claim 10, wherein the conductive coating is configured to detect the one or more electrical signals.

13. The wearable device of claim 10, wherein the conductive coating comprises a biocompatible material that does not interact with a skin of the wearer.

14. The wearable device of claim 10, wherein the conductive coating is composed of at least one of: a diamond like carbon, a tetrahedral amorphous carbon, and a nitride.

15. The wearable device of claim 10, wherein the conductive coating forms one or more traces for conducting an electrical current to one or more electrical components of the wearable device.

16. The wearable device of claim 10, further comprising:
one or more overcoats applied on the conductive coating such that the conductive coating is not in direct contact with a skin of the wearer.

17. A method comprising:
applying one or more thin films to a first surface of a wearable device; and
applying a paint coating to a surface of the one or more thin films to form an aggregate coating,
wherein,
the aggregate coating has an emissivity distribution that includes an ultraviolet (UV) band, a near-infrared (NIR) band, a visible band, and a mid-to-far infrared (IR) band, and the emissivity distribution in the UV and NIR bands is lower than the emissivity distribution in the visible band, and the emissivity distribution in the visible band is lower than the emissivity distribution in the mid-to-far IR band.

18. The method of claim 17, further comprising:
reflecting incident radiation in the UV and NIR bands by the aggregate coating;
radiating incident radiation in the visible band such that the aggregate coating appears as a target color; and
absorbing and re-radiating heat generated by the wearable device in the mid-to-far IR band.

19. The method of claim 17, further comprising:
absorbing and scattering light in the visible band by the paint coating while propagating light outside of the visible band.

20. The method of claim 17, further comprising:
applying a plurality of pigments in the paint coating to selectively absorb and scatter light in the visible band.
